(19) United States
(12) Patent Application Publication
(10) Pub. No.: US 2025/0386507 A1
(43) Pub. Date: Dec. 18, 2025

(54) SEMICONDUCTOR STRUCTURES AND MANUFACTURING METHODS THEREOF, MEMOARY SYSTEMS, AND ELECTRONIC DEVICES

(71) Applicant: Yangtze Memory Technologies Co., Ltd., Wuhan (CN)

(72) Inventors: Zhengliang Xia, Wuhan (CN); Zongliang Huo, Wuhan (CN); Wenbin Zhou, Wuhan (CN); Sizhe Li, Wuhan (CN); Jiaji Wu, Wuhan (CN)

(21) Appl. No.: 19/239,720

(22) Filed: Jun. 16, 2025

Related U.S. Application Data
(60) Provisional application No. 63/661,018, filed on Jun. 17, 2024.

(30) Foreign Application Priority Data
Jul. 19, 2024 (CN) 202410976332.7

(51) Int. Cl. H10B 43/27; G11C 5/06; H10B 43/10; H10B 43/35; H10D 30/01; H10D 30/69

(52) U.S. Cl. CPC H10B 43/27; G11C 5/063; H10B 43/10; H10B 43/35; H10D 30/0413; H10D 30/693

(57) ABSTRACT

The present disclosure provides a semiconductor structure and manufacturing method thereof, a memory system, and an electronic device, which relate to the technical field of semiconductor chip. The semiconductor structure includes a first stack structure including a plurality of channel structures, and a first deck structure, a first intermediate structure and the second deck structure that are stacked. The first intermediate structure is stacked between the first deck structure and the second deck structure, and the channel structures penetrate through the first deck structure, the first intermediate structure and the second deck structure along the stack direction. The first intermediate structure includes the first source layer, the second source layer and the intermediate layer disposed between the first source layer and the second source layer, and the first source layer and the second source layer are connected with the channel structure respectively.

### CROSS-REFERENCE TO RELATED APPLICATIONS

This application claims the benefit of priorities to Chinese Application No. 202410976332.7, filed on Jul. 19, 2024, and U.S. Provisional Application No. 63/661,018, filed on Jun. 17, 2024, both of which are hereby incorporated by reference in their entireties.

### TECHNICAL FIELD

The present disclosure relates to the technical field of semiconductor chip, and in particular to semiconductor structures and manufacturing methods thereof, memory systems, and electronic devices.

### BACKGROUND

Planar processes and fabrication techniques become challenging and costly as the feature size of memory cells in a memory approaching the lower limit, resulting in the storage density of 2D or planar NAND flash memory approaching the upper limit.

To overcome the limitations caused by the 2D or planar NAND flash memory, the industry has developed the memory with a three-dimensional structure (3D NAND), which may increase the storage density by arranging the memory cells above a substrate in three dimensions.

### SUMMARY

Implementations of the present disclosure provide a semiconductor structure and manufacturing method thereof, a memory system, and an electronic device.

Implementation of the present disclosure apply the following technical solution:

In an aspect, an implementation of the present disclosure provides a semiconductor structure. The semiconductor structure may include a first stack structure. The first stack structure may include a plurality of channel structures. The semiconductor structure may further include a first deck structure, a first intermediate structure and a second deck structure that are stacked. The first intermediate structure may be stacked between the first deck structure and the second deck structure. The channel structures may penetrate through the first deck structure, the first intermediate structure and the second deck structure along a stack direction. The first intermediate structure may include a first source layer, a second source layer, and an intermediate layer. The intermediate layer may be disposed between the first source layer and the second source layer. The first source layer and the second source layer may be connected with the channel structures respectively.

In some implementations, the intermediate layer includes a first insulating layer, a conductive layer and a second insulating layer, wherein the conductive layer is disposed between the first insulating layer and the second insulating layer.

In some implementations, the semiconductor structure further includes a first bit line and a second bit line. The first bit line is disposed on a side of the first deck structure away from the first intermediate structure, extends along a first direction, and is connected with one end of a row of channel structures, wherein the first direction is perpendicular to the stack direction. The second bit line is disposed on a side of the second deck structure away from the first intermediate structure, extends along the first direction, and is connected with the other end of the row of channel structures.

In some implementations, the channel structure includes a functional layer and a channel layer which the functional layer surrounds. The channel structure further includes a first channel structure, a second channel structure and a redundant channel structure. The first channel structure is disposed at the first deck structure, and penetrates through the first deck structure along the stack direction, one end of the first channel structure is connected with the first bit line, and the function layer and the channel layer at the other end of the first channel structure are connected with the first source layer. The second channel structure is disposed at the second deck structure, and penetrates through the second deck structure along the stack direction, one end of the second channel structure is connected with the second bit line, and the function layer and the channel layer at the other end of the second channel structure are connected with the second source layer. The redundant channel structure is disposed between the first deck structure and the second deck structure, and extends along the stack direction, one end of the redundant channel structure is connected with the first channel structure, and the other end of the redundant channel structure is connected with the second channel structure.

In some implementations, the channel structure further includes a support column which the function layer and the channel layer surround, and the channel layer is located between the function layer and the support column. The two ends of the support column of the redundant channel structure extend into the first source layer and the second source layer respectively, wherein one end of the support column of the redundant channel structure is connected with the support column of the first channel structure, the other end of the support column of the redundant channel structure is connected with the support column of the second channel structure, and the functional layer of the redundant channel structure is in contact with the intermediate layer.

In some implementations, the channel structure further includes a support column which the function layer and the channel layer surround, and the channel layer is located between the function layer and the support column. The two ends of the support column of the redundant channel structure extend into the first source layer and the second source layer respectively, wherein one end of the support column of the redundant channel structure is connected with the support column of the first channel structure, the other end of the support column of the redundant channel structure is connected with the support column of the second channel structure, and wherein a portion of the support column of the redundant channel structure penetrates through the channel layer and the functional layer along a direction perpendicular to the stack structure, and is in contact with the intermediate layer.

In some implementations, the portion of the support column of the redundant channel structure that penetrates through the channel layer and the functional layer is a set support column, and the boundaries of the set support column are all in contact with the intermediate layer.

In some implementations, the first channel structure includes a first sub-channel structure and a second sub-channel structure. The second sub-channel structure is closer to the first intermediate structure than the first sub-channel structure, and a boundary of the support column of one end of the second sub-channel structure close to the redundant channel structure coincides with a boundary of one end of the support column of the redundant channel structure. The second channel structure includes the third sub-channel structure and the fourth sub-channel structure. The third sub-channel structure is closer to the first intermediate structure than the fourth sub-channel structure, and a boundary of the support column of one end of the third sub-channel structure close to the redundant channel structure coincides with a boundary of the other end of the support column of the redundant channel structure.

In some implementations, a boundary of one end of the first sub-channel structure close to the second sub-channel structure is located outside a boundary of one end of the second sub-channel structure close to the first sub-channel structure. A boundary of one end of the third sub-channel structure close to the fourth sub-channel structure is located outside a boundary of one end of the fourth sub-channel structure close to the third sub-channel structure.

In some implementations, the semiconductor structure further includes a second stack structure. The second stack structure is disposed between the first deck structure and the first bit line, and includes a third deck structure and a plurality of first connection parts. The third deck structure includes two first dielectric layers and a support layer disposed between the two first dielectric layers, the first connection parts penetrate through the third deck structure along the stack direction, and two ends of one of the first connection parts are connected with one of the channel structures and the first bit line respectively.

In some implementations, the semiconductor structure further includes a plurality of second connection parts and a plurality of third connection parts. The second connection parts extend along the stack direction, wherein one of the second connection parts is disposed between one of the first connection parts and the first bit line, and two ends of one of the second connection parts are connected with one of the first connection parts and the first bit line respectively. The third connection parts extend along the stack direction, wherein one of the third connection parts is disposed between one of the channel structures and the second bit line, and two ends of one of the third connection parts are connected with one of the channel structures and the second bit line respectively.

In some implementations, the first deck structure includes a plurality of second dielectric layers and a plurality of first gate layers alternately stacked, and the second deck structure includes a plurality of third dielectric layers and a plurality of second gate layers alternately stacked. The semiconductor structure further includes the third stack structure. The third stack structure includes a fourth deck structure, a fifth deck structure, a second intermediate structure and a connection structure. The fourth deck structure is disposed on a side of the first stack structure along a second direction, and is adjacent to both the first deck structure and the third deck structure. The fifth deck structure is stacked on a side of the fourth deck structure and is adjacent to the second deck structure. The second intermediate structure is disposed between the fourth deck structure and the fifth deck structure, and is adjacent to the first intermediate structure. The connection structure penetrates through the fourth deck structure, the second intermediate structure and the fifth deck structure along the stack direction, and is connected to one of the first gate layers and one of the second gate layers, wherein the second direction is perpendicular to the stack direction and the first direction.

In some implementations, the connection structure includes a connection column, a first connection layer and a second connection layer. The connection column penetrates through the fourth deck structure, the second intermediate structure and the fifth deck structure along the stack direction. The first connection layer is disposed in the fourth deck structure, extends along a direction perpendicular to the stack direction, and is connected with one of the first gate layers. The second connection layer is disposed in the fifth deck structure, extends along a direction perpendicular to the stack direction, and is connected with one of the second gate layers.

In some implementations, the semiconductor structure includes a first region and a second region, wherein the first region is adjacent to the second region, the first stack structure and the second stack structure are both located in the first region, and the third stack structure is located in the second region, wherein the second region is located on a side of the first region in the second direction; alternatively, wherein the first region includes a first sub-region and a second sub-region arranged along the second direction, and the second region is located between the first sub-region and the second sub-region.

In some implementations, the semiconductor structure further includes a gate line slit structure. The gate line slit structure extends along the second direction, and penetrates through the first stack structure and the second stack structure along the stack direction, and is connected with the first source layer and the second source layer, wherein the second direction is perpendicular to the stack direction and the first direction.

In some implementations, the semiconductor structure further includes an interconnect layer. The interconnect layer is disposed on a side of the second bit line away from the first stack structure, and includes a circuit layer and a plurality of interconnect structures, wherein the circuit layer is located between the interconnect structures and the second bit line. The interconnect structure includes a first interconnect structure, a second interconnect structure and a third interconnect structure. The first interconnect structure is connected to the second bit line through the circuit layer, the second interconnect structure is connected to the gate line slit structure through the circuit layer, and the third interconnect structure is connected to the connection structure through the circuit layer.

In some implementations, the semiconductor structure further includes a transistor structure layer. The transistor structure layer is disposed on a side of the interconnect layer away from the second bit line, and includes a first transistor and a second transistor. A first electrode of the first transistor is connected to the second bit line through the interconnect layer, and a second electrode of the first transistor is connected to the gate line slit structure through the interconnect layer, and a control electrode of the second transistor is connected to the connection structure through the interconnect layer.

In other aspect, an implementation of the present disclosure provides a manufacturing method of the semiconductor structure. The method may include forming a first stack structure. The first stack structure may include a plurality of channel structures. The first stack structure may further include a first deck structure, a first intermediate structure and a second deck structure that are stacked. The first intermediate structure may be stacked between the first deck structure and the second deck structure. The channel structures may penetrate through the first deck structure, the first intermediate structure and the second deck structure along a stack direction. The first intermediate structure may include a first source layer, a second source layer and an intermediate layer. The intermediate layer may be disposed between the first source layer and the second source layer. The first source layer and the second source layer may be connected with the channel structures respectively.

In some implementations, forming the first stack structure includes forming a first initial stack structure, the first initial stack structure including a first initial deck structure and a plurality of first sacrifice columns, wherein the first initial deck structure includes a plurality of second dielectric layers and a plurality of first sacrifice layers stacked alternately, and the first sacrifice columns penetrate through the first initial deck structure along the stack direction; stacking a second initial stack structure on a side of the first initial stack structure, the second initial stack structure including a plurality of second sacrifice columns, and a first initial intermediate structure and a second initial deck structure that are stacked, wherein the first initial intermediate structure is disposed between the second initial deck structure and the first initial stack structure, and includes two second sacrifice layers and a third sacrifice layer disposed between the two second sacrifice layers, and wherein the second initial deck structure includes a plurality of third dielectric layers and a plurality of fourth sacrifice layers stacked alternately, and wherein the second sacrifice columns penetrate through the second initial deck structure and the first initial intermediate structure along the stack direction; removing the first sacrifice column and the second sacrifice column and forming the channel structure; replacing the first sacrifice layer with a first gate layer, replacing the two second sacrifice layers with the first source layer and the second source layer respectively, replacing the third sacrifice layer with the intermediate layer, and replacing the fourth sacrifice layer with a second gate layer to form the first stack structure.

In some implementations, before replacing the first sacrifice layer with the first gate layer, replacing the two second sacrifice layers with the first source layer and the second source layer respectively, replacing the third sacrifice layer with the intermediate layer, and replacing the fourth sacrifice layer with the second gate layer, the manufacturing method further includes: forming a gate line slit, the gate line slit extending along a second direction, and penetrating through the first initial deck structure and the second initial deck structure along the stack direction, wherein the second direction is perpendicular to the stack direction and the first direction, and wherein the replacing the first sacrifice layer with the first gate layer, replacing the two second sacrifice layers with the first source layer and the second source layer respectively, replacing the third sacrifice layer with the intermediate layer, and replacing the fourth sacrifice layer with the second gate layer, includes: removing the second sacrifice layers through the gate line slit to form first gap layers; forming the first source layer and the second source layer in two of the first gap layers respectively; removing the first sacrifice layer, the third sacrifice layer and the fourth sacrifice layer through the gate line slit to form a second gap layer, a third gap layer and a fourth gap layer; and forming the first gate layer in the second gap layer, forming the intermediate layer in the third gap layer, and forming the second gate layer in the fourth gap layer.

In some implementations, before forming the first source layer and the second source layer in two of the first gap layers respectively, the manufacturing method further includes removing a portion of the channel structure through two of the first gap layers respectively, to form a redundant channel structure.

In some implementations, before forming the first stack structure, the manufacturing method of the semiconductor structure further includes forming a second stack structure. The second stack structure is formed on a side of the first initial stack structure away from the second initial stack structure. Forming the second stack structure includes: forming a third initial stack structure including a third initial deck structure and a plurality of third sacrifice columns, wherein the third initial deck structure includes two first dielectric layers and a fifth sacrifice layer, and wherein the third sacrifice columns penetrate through the third initial deck structure along the stack direction, and one end of one of the third sacrifice columns is connected with one end of one of the channel structures; replacing the fifth sacrifice layer with a support layer; and removing the third sacrifice column and forming the first connection part, to form the second stack structure.

In some implementations, removing the third sacrifice column and forming the first connection part includes: removing the third sacrifice column to form a first through hole, wherein the first through hole exposes one end of the channel structure; removing a portion of the channel structure through the first through hole to form a second through hole, wherein the second through hole exposes a functional layer, a channel layer and a support column of the channel structure; and forming the first connection part in the second through hole.

In some implementations, forming the first stack structure includes: forming a fourth initial stack structure including a fourth initial deck structure and a plurality of fourth sacrifice columns, wherein the fourth initial deck structure includes a plurality of fourth dielectric layers and a plurality of sixth sacrifice layers stacked alternately, and the fourth sacrifice column penetrates through the fourth initial deck structure along the stack direction; stacking a fifth initial stack structure on a side of the fourth initial stack structure, the fifth initial stack structure including a plurality of fifth sacrifice columns, and a fifth initial deck structure, a second initial intermediate structure and a sixth initial deck structure that are stacked, wherein the fifth initial deck structure includes a plurality of fifth dielectric layers and a plurality of seventh sacrifice layers stacked alternately, the second initial intermediate structure includes two eighth sacrifice layers and a ninth sacrifice layer disposed between two eighth sacrifice layers, and the sixth initial deck structure includes a plurality of sixth dielectric layers and a plurality of tenth sacrifice layers stacked alternately; and wherein the fifth sacrifice columns penetrate through the fifth initial deck structure, the second initial intermediate structure and the sixth initial deck structure along the stack direction, and one end of one of the fifth sacrifice columns is connected with one end of one of the fourth sacrifice columns; forming a sixth initial stack structure on a side of the fifth initial stack structure away from the fourth initial stack structure, the sixth initial stack structure including a seventh initial deck structure and a plurality of sixth sacrifice columns, wherein the seventh initial deck structure includes a plurality of seventh dielectric layers and a plurality of eleventh sacrifice layers stacked alternately; and wherein the sixth sacrifice columns penetrate through the seventh initial deck structure along the stack direction, and one end of one of the sixth sacrifice column is connected to the other end of one of the fifth sacrifice columns; removing the fourth sacrifice column, the fifth sacrifice column, and the sixth sacrifice column, and forming the channel structure; replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer both with the second gate layer to form the first stack structure.

In some implementations, before replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer with the second gate layer, the manufacturing method further includes: forming a gate line slit extending along the second direction, and penetrating the fourth initial stack structure, the fifth initial stack structure and the sixth initial stack structure along the stack direction, wherein the second direction is perpendicular to the stack direction and the first direction; and wherein the replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer with the second gate layer, includes: removing the ninth sacrifice layer through the gate line slit to form fifth gap layers; forming the first source layer and the second source layer in two of the fifth gap layers respectively; removing the sixth sacrifice layer, the seventh sacrifice layer, the eighth sacrifice layer, the tenth sacrifice layer and the eleventh sacrifice layer through the gate line slit to form a sixth gap layer, a seventh gap layer, an eighth gap layer, a ninth gap layer and a tenth gap layer; and forming the first gate layer in both the sixth gap layer and the seventh gap layer, forming the intermediate layer in the eighth gap layer, and forming the second gate layer in both the ninth gap layer and the tenth gap layer.

In some implementations, before forming the first source layer and the second source layer in the two fifth gap layers respectively, the manufacturing method further includes removing a portion of the channel structure through two of the fifth gap layers respectively, to form a redundant channel structure.

In some implementations, the manufacturing method further includes forming a gate line slit structure in the gate line slit, wherein the gate line slit structure is connected to both the first source layer and the second source layer.

On other aspect, an implementation of the present disclosure provides a memory system. The memory system may include a semiconductor structure and a controller. The semiconductor structure may include a first stack structure. The first stack structure may include a plurality of channel structures. The semiconductor structure may further include a first deck structure, a first intermediate structure and a second deck structure that are stacked. The first intermediate structure may be stacked between the first deck structure and the second deck structure. The channel structures may penetrate through the first deck structure, the first intermediate structure and the second deck structure along a stack direction. The first intermediate structure may include a first source layer, a second source layer, and an intermediate layer. The intermediate layer may be disposed between the first source layer and the second source layer. The first source layer and the second source layer may be connected with the channel structures respectively. The controller may be coupled to the semiconductor structure to control the semiconductor structure to store data.

On other aspect, an implementation of the present disclosure provides an electronic device comprising a motherboard and a memory system disposed on the motherboard. The memory system may include a semiconductor structure and a controller. The semiconductor structure may include a first stack structure. The first stack structure may include a plurality of channel structures. The semiconductor structure may further include a first deck structure, a first intermediate structure and a second deck structure that are stacked. The first intermediate structure may be stacked between the first deck structure and the second deck structure. The channel structures may penetrate through the first deck structure, the first intermediate structure and the second deck structure along a stack direction. The first intermediate structure may include a first source layer, a second source layer, and an intermediate layer. The intermediate layer may be disposed between the first source layer and the second source layer. The first source layer and the second source layer may be connected with the channel structures respectively. The controller may be coupled to the semiconductor structure to control the semiconductor structure to store data.

### BRIEF DESCRIPTION OF THE DRAWINGS

In order to illustrate the technical solutions in the present disclosure more clearly, the drawings to be used in some implementations of the present disclosure will be briefly introduced below. Apparently, the drawings in the following description are only drawings of some implementations of the present disclosure. Those of ordinary skills in the art may also obtain other drawings according to these drawings. In addition, the drawings in the following description may be regarded as schematic diagrams, instead of limitations to an actual size of a product, an actual flow of a method, an actual timing of a signal, etc. involved in the implementations of the present disclosure.

FIG. 1 is a structural block diagram of an electronic device provided by some implementations of the present disclosure.

FIG. 2 is a structural block diagram of a memory provided by some implementations of the present disclosure.

FIG. 3 is a stereoscopic structural diagram of a memory provided by some implementations of the present disclosure.

FIG. 4 is a structural diagram of a semiconductor structure provided by some implementations of the present disclosure.

FIG. 5 is a structural diagram of other semiconductor structure provided by some implementations of the present disclosure.

FIG. 6 is a structural diagram of another semiconductor structure provided by some implementations of the present disclosure.

FIG. 7 is a structural diagram of another semiconductor structure provided by some implementations of the present disclosure.

FIG. 8 is a structural diagram of another semiconductor structure provided by some implementations of the present disclosure.

FIG. 9 is a structural diagram of another semiconductor structure provided by some implementations of the present disclosure.

FIG. 10 is a top view diagram of a semiconductor structure provided by some implementations of the present disclosure.

FIG. 11 is a stitching diagram of the cross section of AA ‘and BB’ in FIG. 10.

FIG. 12 is a top view diagram of other semiconductor structure provided by some implementations of the present disclosure.

FIG. 13 is a structural diagram of another semiconductor structure provided by some implementations of the present disclosure.

FIG. 14 is a flow chart of a manufacturing method of a second stack structure provided by some implementations of the present disclosure.

FIG. 15 is a structural diagram of a third initial stack structure corresponding to the manufacturing method of FIG. 14.

FIG. 16 is a structural diagram of a semiconductor structure corresponding to the manufacturing method of FIG. 14.

FIG. 17 is a flow chart of a manufacturing method of a first stack structure provided by some implementations of the present disclosure.

FIG. 18 is a structural diagram of a semiconductor structure corresponding to the manufacturing method of FIG. 17.

FIG. 19 is a structural diagram of other semiconductor structure corresponding to the manufacturing method in FIG. 17.

FIG. 20 is a structural diagram of another semiconductor structure corresponding to the manufacturing method in FIG. 17.

FIG. 21 is a structural diagram of another semiconductor structure provided by some implementations of the present disclosure.

FIG. 22 is a flow chart of a manufacturing method of other first stack structure provided by some implementations of the present disclosure.

FIG. 23 is a structural diagram of a semiconductor structure corresponding to the manufacturing method of FIG. 22.

FIG. 24 is a structural diagram of a semiconductor structure corresponding to the manufacturing process provided by some implementations of the present disclosure.

FIG. 25 is a flow chart of a manufacturing method of a first connection part provided by some implementations of the present disclosure.

FIG. 26 is a structural diagram of a semiconductor structure corresponding to the manufacturing method of FIG. 25.

FIG. 27 is a structural diagram of other semiconductor structure corresponding to the manufacturing method of FIG. 25.

FIG. 28 is a flow chart of a manufacturing method of another first stack structure provided by some implementations of the present disclosure.

FIG. 29 is a structural diagram of a semiconductor structure corresponding to the manufacturing method in FIG. 28.

FIG. 30 is a structural diagram of other semiconductor structure corresponding to the manufacturing method in FIG. 28.

FIG. 31 is a structural diagram of another semiconductor structure corresponding to the manufacturing method in FIG. 28.

FIG. 32 is a structural diagram of other semiconductor structure corresponding to the manufacturing process provided by some implementations of the present disclosure.

FIG. 33 is a flow chart of a manufacturing method of another first stack structure provided by some implementations of the present disclosure.

FIG. 34 is a structural diagram of a semiconductor structure corresponding to the manufacturing method in FIG. 33.

FIG. 35 is a structural diagram of a semiconductor structure corresponding to the manufacturing method in FIG. 33.

FIG. 36 is a structural diagram of another semiconductor structure corresponding to the manufacturing process provided by some implementations of the present disclosure.

FIG. 37 is a structural diagram of another semiconductor structure corresponding to the manufacturing process provided by some implementations of the present disclosure.

FIG. 38 is a structural diagram of another semiconductor structure corresponding to the manufacturing process provided by some implementations of the present disclosure.

### DETAILED DESCRIPTION

The technical solutions in some implementations of the present disclosure will be described below clearly and completely in conjunction with the drawings. Apparently, the implementations described are only part of, but not all of, the implementations of the present disclosure. All other implementations obtained by those of ordinary skills in the art based on the implementations provided by the present disclosure should fall within the scope of protection of the present disclosure.

Unless otherwise specified in the context, throughout the specification and the claims, the term “comprise” is interpreted as an open and inclusive meaning, i.e., “including, but not limited to”. In the description of the specification, the terms “one implementation”, “some implementations”, “an example implementation”, “one example”, or “some examples”, etc. are intended to indicate that particular features, structures, materials, or characteristics related to the implementation or example are included in at least one implementation or example of the present disclosure. The schematic representation of the above terms may not necessarily refer to the same implementation or example. Furthermore, the particular features, structures, materials, or characteristics described may be included in any one or more implementations or examples in any suitable manner.

Hereinafter, the terms “first” and “second” are used for descriptive purposes only, and cannot be construed as indicating or implying relative importance or implicitly indicating the number of technical features indicated. Thus, features defined by “first” or “second” may explicitly or implicitly include one or more such features. In the description of implementations of the present disclosure, “a plurality of” means two or more, unless otherwise stated.

In describing some implementations, the expressions “couple” and “connect” and their derivatives may be used. For example, some implementations may be described using the term “connect” to indicate that two or more parts are in direct physical or electrical contact with each other. Further, some implementations may be described using the term “couple” to indicate that two or more parts are in direct physical or electrical contact. However, the term “couple” may further refer to two or more parts that are not in direct contact with each other, but still cooperate or interact with each other. The implementations disclosed herein are not necessarily limited to the content herein.

Example implementations are described herein with reference to at least one of a cross-sectional view or a planar view used as an idealized example drawing. In the drawings, thicknesses of layers and areas are exaggerated for clarity. Thus, changes in shapes relative to the drawings caused by, for example, at least one of a manufacturing technology or a tolerance, may be contemplated. Therefore, the example implementations should not be interpreted as being limited to the shapes of areas shown herein, but rather comprise shape deviations caused by, for example, manufacturing. For example, an etching area shown as a rectangle will typically have a curved feature. Therefore, the areas shown in the drawings are schematic essentially, and their shapes are neither intended to show actual shapes of areas of a device, nor intended to limit the scope of the example implementations.

As used herein, the term “substrate” refers to a material on which subsequent layers of material may be added. The substrate itself may be patterned. The material added to the substrate may be patterned or may remain unpatterned. In addition, the substrate may include a variety of semiconductor materials such as silicon, germanium, gallium arsenide, indium phosphide, etc. Instead, the substrate may be made of non-conductive materials such as glass, plastic, or sapphire wafer.

The term “three-dimensional memory” refers to a semiconductor device formed by strings of memory cell transistors arranged in an array on the main surface of the substrate or source layer and extending in a direction perpendicular to the substrate or source layer. As used herein, the term “vertically/vertically” means the main surface (i.e., the lateral surface) that is nominally perpendicular to the substrate or source layer.

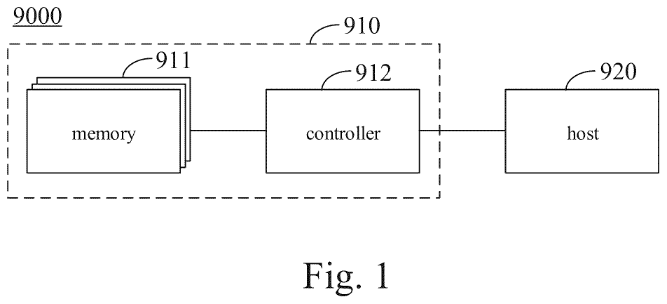

FIG. 1 is a structural block diagram of an electronic device 9000 provided by some implementations of the present disclosure. The electronic device 9000 may be a mobile phone, a desktop computer, a laptop computer, a tablet computer, a vehicle computer, a game console, a printer, a positioning device, a wearable electronic device (such as a smart watch, a smart bracelet, a smart glasses, etc.), a smart sensor, a virtual reality (VR) device, an argument reality (AR) device, or any other suitable electronic device having storage therein.

As shown in FIG. 1, the electronic device 9000 may include a memory system 910 and a host 920, wherein the memory system 910 may be integrated into various types of storage devices, for example, a memory card. The memory cards include any one of PC card (PCMCIA, Personal Computer Memory Card International Association), compact flash (CF) card, smart media (SM) card, memory stick, multimedia card (MMC), secure digital memory card (SD), universal flash storage (UFS). In other words, the memory system 910 may be applied to and packaged into different types of electronic products.

The host 920 may include a processor of the electronic device 9000, such as a central processing unit (CPU), or a system-on-chip (SoC), such as an application processor (AP). The host 920 may be configured to send or receive data to or from the memory.

In some implementations, the memory system 910 may have one or more memory 911 and a controller 912. In an example, the controller 912 may be configured for operating in low-duty-cycle environment, such as SD cards, CF cards, universal serial bus (USB) flash drives, or other media for use in electronic devices such as personal computers, digital cameras, and mobile phones, etc. Alternatively, in other examples, the controller 912 is configured for operating in a high-duty-cycle environment SSDs or eMMCs, which are used as data storage for mobile devices such as smart phones, tablets, laptop computers, etc., and enterprise storage arrays. Alternatively, in some examples, the controller 912 is coupled to the memory 911 and the host 920, and is configured to control data in the memory 911 while communicating with external devices, such as the host.

The number of memory 911 in the memory system 910 may be one or more, as illustrated in FIG. 1 with three memories 911 as an example. The controller 912 may manage the data stored in each of the memories 911 and communicate with the host 920. The controller 912 may be configured to control the operations of each of the memories 911, such as read, write, and refresh operations. The controller 912 may further be configured to manage various functions regarding the data stored or to be stored in each of the memories 911, including but not limited to refresh and timing control, command/request translation, buffering and scheduling, and power management. In some implementations, the controller 912 is further configured to determine the maximum storage capacity that may be used by the computer system, the number of memory banks, the memory type and speed, the memory grain data depth and data width, and other important parameters. Any other suitable function may further be performed by the controller 912. The controller 912 may communicate with external devices (for example, host 920) according to a communication protocol. For example, the controller 912 may communicate with external devices through at least one of various interface protocols, such as a USB protocol, an MMC protocol, a peripheral component interconnection (PCI) protocol, a PCI express (PCI-E) protocol, an advanced technology attachment (ATA) protocol, a serial ATA protocol, a parallel ATA protocol, a small computer small interface (SCSI) protocol, an enhanced small disk interface (EDSI) protocol, an integrated drive electronics (IDE) protocol, a Firewire protocol, etc.

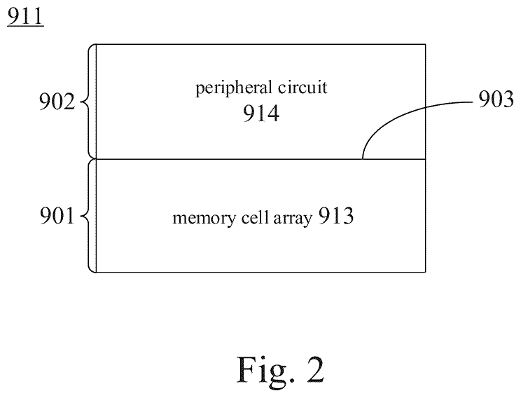

FIG. 2 is a structural block diagram of the memory 911 provided by some implementations of the present disclosure. As shown in FIG. 2, the memory 911 includes a memory cell array 913 and a peripheral circuit 914 for controlling the memory cell array 913, the peripheral circuit 914 (also referred to “control and sensing circuits”) may include any suitable digital, analog and/or mixed-signal circuits used for facilitating the operations of the memory cell array 913. For example, the peripheral circuit 914 may include one or more of a page buffer, a decoder (e.g., a row decoder and a column decoder), a sense amplifier, a driver (e.g., word line driver), an input/output (I/O) circuit, a charge pump, a voltage source or generator, a current or voltage reference, any portions (e.g., sub-circuit) of the functional circuits mentioned above, or any active or passive components of the circuit (e.g., transistors, diodes, resistors, or capacitors).

In an example, the peripheral circuit 914 may use complementary metal-oxide-semiconductor (CMOS) technology, for example, which may be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.).

The memory cell array 913 and the peripheral circuit 914 may be arranged side by side in the same plane, for example, on the same wafer, that is, the memory cell array 913 and the peripheral circuit 914 may be located in the same semiconductor structure. The memory cell array 913 and the peripheral circuit 914 may further be formed on different wafers and bonded together in a face-to-face manner. As shown in FIG. 2, when the memory cell array 913 and the peripheral circuit 914 are formed on different wafers and bonded together in a face-to-face manner, the memory 911 may include a first semiconductor structure 901 and a second semiconductor structure 902 and a bonding interface 903 between the first semiconductor structure 901 and the second semiconductor structure 902.

The first semiconductor structure 901 may include a memory cell array 913, and the second semiconductor structure 902 may include a peripheral circuit 914. A large number of interconnects (e.g., bonding contacts) may be formed across the bonding interface 903 to make direct, short-distance (e.g., micron-level) electrical connections between the first semiconductor structure 901 and the second semiconductor structure 902, as opposed to the long distance (e.g., millimeter or centimeter-level) chip-to-chip data bus on the circuit board (e.g., printed circuit board (PCB)), thereby eliminating chip interface latency and achieving high-speed I/O throughput with reduced power consumption. The transfer of data between the memory cell array in the first semiconductor structure 901 and the peripheral circuit in the second semiconductor structure 902 may be performed through the interconnects (e.g., bonding contacts) across the bonding interface 903. By vertically integrating the first semiconductor structure 901 and the second semiconductor structure 902, the chip size may be reduced and the storage density of the memory 911 may be increased.

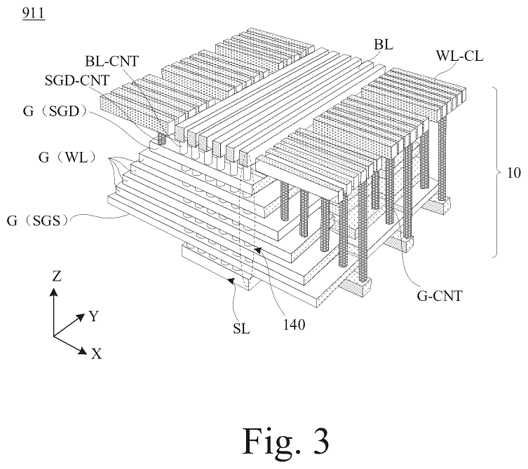

FIG. 3 is a stereoscopic structural diagram of a memory 911 provided by some implementations of the present disclosure.

As shown in FIG. 3, the memory 911 may include a stack structure 10, a source layer SL coupled to the stack structure 10, and a peripheral device coupled to the stack structure 10. The peripheral device may be disposed on a side of the stack structure 10 away from the source layer SL.

The source layer SL may include semiconductor materials such as single crystal silicon, single crystal germanium, group III-V compound semiconductor materials, group II-VI compound semiconductor materials, and other suitable semiconductor materials. The source layer SL may be partially or completely doped. In an example, the source layer SL may include a doping region, which is doped with a p-type dopant. The source layer SL may further include an undoped region.

The stack structure 10 may include strings of memory cell transistors (referred to as “memory strings” herein, for example NAND memory strings) arranged in an array. The source layer SL may be coupled with the source end of a plurality of memory strings. As shown in FIG. 3, the memory string may include a channel structure 140 and a plurality of gate lines G, which may be disposed around the channel structure 140.

In some examples, along the stack direction Z, the bottommost gate line among the plurality of gate lines G (for example, the gate line of the plurality of gate lines G closest to the source layer SL) is constructed as the source selection gate SGS, and the uppermost gate line among the plurality of gate lines G (for example, the gate line of the plurality of gate lines G farthest from the source layer SL) is constructed as the drain selection gate SGD, and the gate lines in the middle among a plurality of gate lines G may be constructed as a plurality of word lines WL, including, for example, a word line WL0, a word line WL1, a word line WL2, and a word line WL3. By writing different voltages on the word lines WL, the data writing, reading, and erasing of each memory cell (for example, transistor T) in the memory string may be completed.

In an example, by the provided gate line contacts G-CNT, the gate line G may be led out, and then the voltage on the gate line G may be written through the gate line contacts G-CNT, so as to realize the control of the memory string in the stack structure 10. However, with the increase of the height of the stack structure 10 in the stack direction Z, the distance between the memory string and the source layer SL gradually increases, which leads to the increase of the loss of the memory string in the signal transmission, the reduction of the current value in the memory string, and even affects the electrical performance of the memory 911.

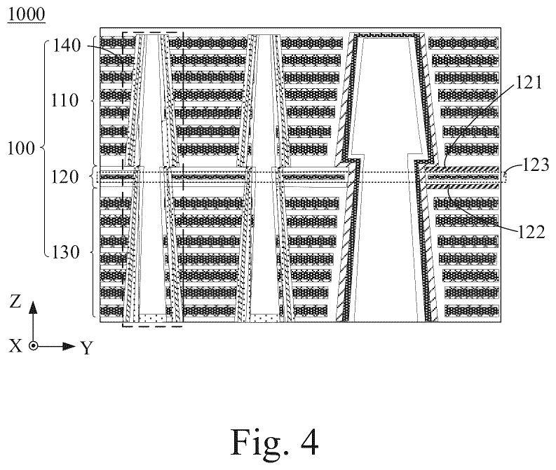

FIG. 4 is a structural diagram of a semiconductor structure 1000 provided by some implementations of the present disclosure.

As shown in FIG. 4, in some implementations, the semiconductor structure 1000 includes the first stack structure 100. The first stack structure 100 includes a plurality of channel structures 140, and a first deck structure 110, a first intermediate structure 120 and a second deck structure 130 that are stacked. The first intermediate structure 120 is stacked between the first deck structure 110 and the second deck structure 130, and the channel structures 140 penetrate through the first deck structure 110, the first intermediate structure 120 and the second deck structure 130 along the stack direction Z, wherein the first intermediate structure 120 includes a first source layer 121, a second source layer 122 and an intermediate layer 123, and the intermediate layer 123 is disposed between the first source layer 121 and the second source layer 122, and the first source layer 121 and the second source layer 122 are connected with the channel structures 140 respectively.

FIG. 4 is for illustrative purposes only and actually may not necessarily reflect the actual device structure (e.g., interconnect, etc.).

In the implementation, by the first intermediate structure 120 disposed between the first deck structure 110 and the second deck structure 130, the electrical signals may be provided for the channel structures 140 in the first deck structure 110 and the second deck structure 130 respectively through the first source layer 121 and the second source layer 122 in the first intermediate structure 120, thereby shortening the distances between the channel structures 140 in the first deck structure 110 and the second deck structure 130 on both sides of the first intermediate structure 120 and their corresponding source layers, so as to reduce the loss of signal transmission in the channel structures 140 in the first deck structure 110 and the second deck structure 130 on both sides of the first intermediate structure 120, and in turn improving the electrical performance of the entire first stack structure 100.

In addition, by the first intermediate structure 120 disposed between the first deck structure 110 and the second deck structure 130, the height of the first deck structure 110 and the second deck structure 130 on both sides may be appropriately increased, thereby realizing an increase in the height of the first stack structure 100 on the premise of ensuring the good electrical performance of the first stack structure 100, so as to increase the storage capacity of the semiconductor structure 1000.

In addition, in the implementation, by the intermediate layer 123 between the first source layer 121 and the second source layer 122, the isolation between the first source layer 121 and the second source layer 122 may be implemented, so as to avoid the interference of the first source layer 121 or the second source layer 122 to one another when a voltage is applied. The stability and reliability of the semiconductor structure 1000 may be improved by avoiding the influence of mutual interference between them on the electrical performance of the semiconductor structure 1000.

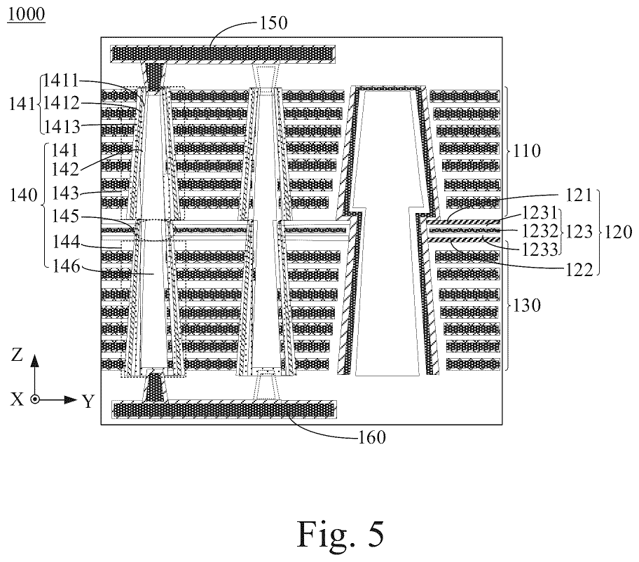

FIG. 5 is a structural diagram of other semiconductor structure 1000 provided by some implementations of the present disclosure.

As shown in FIG. 5, in some implementation, the intermediate layer 123 includes a first insulating layer 1231, a conductive layer 1232 and a second insulating layer 1233, and the conductive layer 1232 is disposed between the first insulating layer 1231 and the second insulating layer 1233.

In the implementation, the insulation between the conductive layer 1232 and the first source layer 121 and the second source layer 122 on both sides thereof may be implemented by the provided first insulating layer 1231 and second insulating layer 1233. In some implementations, the shielding processing between the first source layer 121 and the second source layer 122 may be implemented by applying a voltage on the conductive layer 1232, to avoid the mutual interference between the first source layer 121 and the second source layer 122.

In some examples, the insulating materials of the first insulating layer 1231 and the second insulating layer 1233 include, but are not limited to, one or more of oxide materials (e.g., silicon oxide), nitride materials (e.g., silicon nitride), and nitrogen oxide materials (e.g., silicon oxynitride). The material of the first insulating layer 1231 may be the same as or different from that of the second insulating layer 1233.

In an example, conductive materials of conductive layer 1232 include, but are not limited to, W, Co, Cu, Al, doped silicon, silicide, or any combination thereof.

Continuing to refer to FIG. 5, in some implementations, the semiconductor structure 1000 further includes a first bit line 150 and a second bit line 160. The first bit line 150 is disposed on the side of the first deck structure 110 away from the first intermediate structure 120, the first bit line 150 extends along the first direction Y, and the first bit line 150 is connected with one end of a row of channel structures 140, wherein the first direction Y is perpendicular to the stack direction Z. The second bit line 160 is disposed on the side of the second deck structure 130 away from the first intermediate structure 120, extends along the first direction Y, and is connected with the other end of the row of channel structures 140.

In the implementation, the corresponding channel structures 140 in first deck structure 110 and the second deck structure 130 may be controlled respectively by the provided first bit line 150 and the second bit line 160. As a feasible implementation, the first bit line 150 may control a portion of the channel structure 140 located in the first deck structure 110, and the second bit line 160 may control a portion of the channel structure 140 located in the second deck structure 130.

With such configuration, the segmented control of one of the channel structures 140 may be implemented, so as to shorten the distance between a single bit line (the first bit line 150 or the second bit line 160) and its corresponding controlled portion of the channel structure 140, thereby shortening the length of the line and reducing the line loss, so as to improve the current value in the channel structure 140, and thereby improving the electrical performance of the semiconductor structure 1000.

In addition, since the control of channel structure 140 by the single-side bit line is limited by the height of channel structure 140, in the present implementation, by the provided first bit line 150 and the second bit line 160 on both sides of semiconductor structure 1000 respectively, and the increasing of the height of the portion of channel structure 140 each corresponding to the two bit lines, the height of the whole channel structure 140 may be increased, thereby improving the storage capacity of the semiconductor structure 1000.

In the example, a plurality of channel structures 140 may be arranged in a plurality of rows and columns, the number of the first bit line 150 and the second bit line 160 may be one or more, and a plurality of first bit lines 150 and second bit lines 160 may be arranged at intervals along the second direction X and extend along the first direction Y. One of the first bit lines 150 and one of the second bit lines 160 are connected with a row of the channel structures 140 correspondingly, so as to implement the control of data reading, writing or erasing operations of the channel structures 140, wherein the second direction X is perpendicular to the stack direction Z and the first direction Y.

Continuing to refer to FIG. 5, in some implementations, the channel structure 140 includes a functional layer 141 and a channel layer 142, and the functional layer 141 surrounds the channel layer 142. The channel structure 140 further includes a first channel structure 143, a second channel structure 144, and a redundant channel structure 145. The first channel structure 143 is disposed on the first deck structure 110, and penetrates through the first deck structure 110 along the stack direction Z. One end of the first channel structure 143 is connected with the first bit line 150, and the function layer 141 and channel layer 142 at the other end of the first channel structure 143 are connected with the first source layer 121. The second channel structure 144 is disposed on the second deck structure 130 and penetrates through the second deck structure 130 along the stack direction Z. One end of the second channel structure 144 is connected with the second bit line 160, and the function layer 141 and channel layer 142 at the other end of the second channel structure 144 are connected with the second source layer 122. The redundant channel structure 145 is disposed between the first deck structure 110 and the second deck structure 130. The redundant channel structure 145 extends along the stack direction Z, and one end of the redundant channel structure 145 is connected with the first channel structure 143, and the other end of the redundant channel structure 145 is connected with the second channel structure 144.

In some examples, the manufacture of the channel structure 140 in the first stack structure 100 may include the manufacturing process of pre-etching the through hole, and then successively forming the functional layer 141 and channel layer 142 in the through hole. However, with the gradual increase of the height of the first stack structure 100, there are higher requirements and challenges for the etching process of the through hole. Based on this, in the implementation, the multiple stacking technology may be used for etching the through hole with a larger height, so as to obtain a channel structure 140 with a larger height, thereby improving the storage capacity of the semiconductor structure 1000. The manufacturing process of multiple stacking technology will be introduced in the manufacturing method of semiconductor structure 1000 later, and will not be repeated here.

In the implementation, based on the manufacturing process of the above multiple stacking technology, the number of the deck structures included in the first stack structure 100 may be any number that meets the requirements of the implementation, such as 2, 3, 4, etc. In the following, the implementation takes the number of deck structures is 2 (that is, the first deck structure 110 and the second deck structure 130) as an example to introduce the semiconductor structure 1000. In an example, the first intermediate structure 120 in the implementation may be located between two adjacent deck structures.

Combined with the first bit line 150 and the second bit line 160 mentioned above, a portion of the channel structure 140 (the first channel structure 143) in the first deck structure 110 may read, write or erase data under the control of the first bit line 150, and a portion of the channel structure 140 (the second channel structure 144) in the second deck structure 130 may read, write or erase data under the control of the second bit line 160.

As a feasible implementation, the first source layer 121 may be used as the source layer of the first channel structure 143 in the first deck structure 110, so as to provide electrical signals for the operation of the channel layer 142 of the first channel structure 143 in the first deck structure 110. The second source layer 122 may be used as the source layer of the second channel structure 144 in the second deck structure 130, so as to provide electrical signals for the operation of the channel layer 142 of the second channel structure 144 in the second deck structure 130.

In some examples, the functional layer 141 may include a tunneling layer 1411, a charge trapping layer 1412, and a charge blocking layer 1413, wherein the charge trapping layer 1412 is disposed between the tunneling layer 1411 and the charge blocking layer 1413, and the charge blocking layer 1413 is farther away from the channel layer 142 than the tunneling layer 1411.

Continuing to refer to FIG. 5, in some implementation, the channel structure 140 further includes a support column 146, which the functional layer 141 and the channel layer 142 surround, and the channel layer 142 is located between the functional layer 141 and the support column 146. The two ends of the support column of the redundant channel structure 145 extend into the first source layer 121 and the second source layer 122 respectively, and one end of the support column of the redundant channel structure 145 is connected with the support column of the first channel structure 143, and the other end of the support column of the redundant channel structure 145 is connected with the support column of the second channel structure 144. The functional layer of the redundant channel structure 145 is in contact with the intermediate layer 123.

Based on the manufacturing process of semiconductor structure 1000, the support column of the first channel structure 143, the support column of the second channel structure 144 and the support column of the redundant channel structure 145 may be obtained in the same manufacturing process. Therefore, the two ends of the support column of the redundant channel structure 145 are connected with the support column of the first channel structure 143 and the support column of the second channel structure 144 respectively.

In addition, in the implementation, also based on the manufacturing process of semiconductor structure 1000, the first intermediate structure 120 is manufactured such that the first source layer 121 and the second source layer 122 in the first intermediate structure 120 penetrate through the functional layer 141 of the channel structure 140 and are connected with the channel layer 142, so as to separate the functional layer 141 of the channel structure 140, thereby separating the channel structure into the first channel structure 143, the second channel structure 144 and the redundant channel structure 145. The intermediate layer 123 of the first intermediate structure 120 is in contact with the functional layer of the redundant channel structure 145, because the first intermediate structure 120 adopts the characteristic of the sandwich structure.

With such configuration, the first source layer 121 and the second source layer 122 can be isolated by using the structural feature that the intermediate layer 123 is in contact with the functional layer of the redundant channel structure 145, so as to avoid the mutual interference between the first source layer 121 and the second source layer 122, and thereby improving the electrical performance of the semiconductor structure 1000.

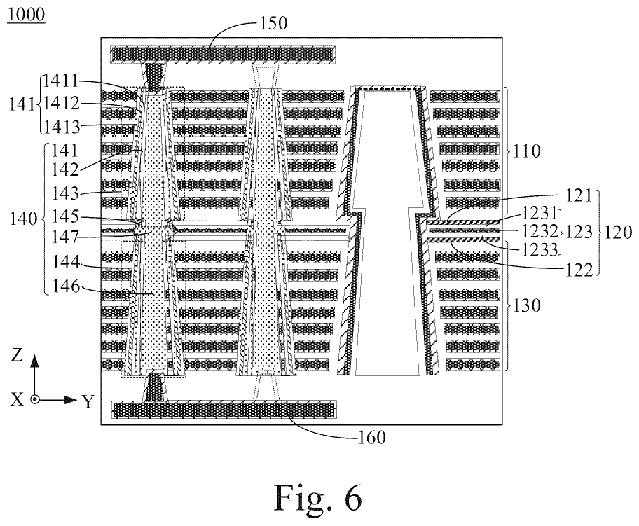

FIG. 6 is a structural diagram of another semiconductor structure 1000 provided by some implementations of the present disclosure.

As shown in FIG. 6, in some implementations, the channel structure 140 further includes the support column 146, which the functional layer 141 and the channel layer 142 surround, and the channel layer 142 is located between the functional layer 141 and the support column 146. The two ends of the support column of the redundant channel structure 145 extend into the first source layer 121 and the second source layer 122 respectively, and one end of the support column of the redundant channel structure 145 is connected with the support column of the first channel structure 143, and the other end of the support column of the redundant channel structure 145 is connected with the support column of the second channel structure 144. A portion of the support column of the redundant channel structure 145 penetrates through the channel layer 142 and the functional layer 141 along a direction perpendicular to the deck structure, and is in contact with the intermediate layer 123.

In the example, also based on the manufacturing process of semiconductor structure 1000, the support column of the first channel structure 143, the support column of the second channel structure 144 and the support column of the redundant channel structure 145 may be obtained in the same manufacturing process. Therefore, the two ends of the support column of the redundant channel structure 145 are connected with the support column of the first channel structure 143 and the support column of the second channel structure 144, respectively.

In addition, in the implementation, the first source layer 121 and the second source layer 122 in the first intermediate structure 120 penetrate through the functional layer 141 of the channel structure 140 and are connected with the channel layer 142, thereby manufacturing the first channel structure 143, the second channel structure 144 and the redundant channel structure 145.

In the implementation, a portion of the support column of the redundant channel structure 145 penetrates through the channel layer 142 and the function layer 141 along a direction perpendicular to the deck structure (i.e., the horizontal direction), so as to break the channel layer 142 of the redundant channel structure 145, and thereby preventing the first source layer 121 and the second source layer 122 from being electrically connected via the channel layer 142 of the redundant channel structure 145, so that the complete isolation of the first source layer 121 and the second source layer 122 may be independent of each other.

With such configuration, the first source layer 121 and the second source layer 122 can be completely isolated by using the intermediate layer 123 and the portion of the support column of the redundant channel structure 145 that penetrates through the channel layer 142 and the function layer 141, so as to improve the isolation effect between the first source layer 121 and the second source layer 122, and thereby improving the electrical performance of the semiconductor structure 1000.

Continuing to refer to FIG. 6, in some implementations, the portion of the support column of the redundant channel structure 145 that penetrates through the channel layer 142 and the functional layer 141 is the set support column 147, and the boundaries of the set support column 147 are all in contact with the intermediate layer 123.

By making the boundaries of the set support column 147 contact with the intermediate layer 123, the complete penetration of the channel layer 142 and the functional layer 141 may be realized, so as to avoid that the first source layer 121 and the second source layer 122 may be electrically connected through the channel layer 142 of the redundant channel structure 145 in case of the partial penetration of the set support column 147 to the channel layer 142 and the functional layer 141, resulting in a reduced isolation effect between the first source layer 121 and the second source layer 122.

With such configuration, the complete isolation between the first source layer 121 and the second source layer 122 may be realized, so as to improve the isolation effect between the first source layer 121 and the second source layer 122, and thereby improving the reliability of the semiconductor structure 1000.

In the foregoing implementations, the semiconductor structure 1000 is introduced by taking the first intermediate structure 120 between two adjacent deck structures as an example. In the following, the semiconductor structure 1000 is introduced by taking the first intermediate structure 120 located inside a deck structure (for example, disposed between two dielectric layers of one deck structure) as an example.

In an example, the number of deck structures in the implementation is 3, and the first intermediate structure 120 is disposed in the target deck structure 170 in the middle position of three deck structures.

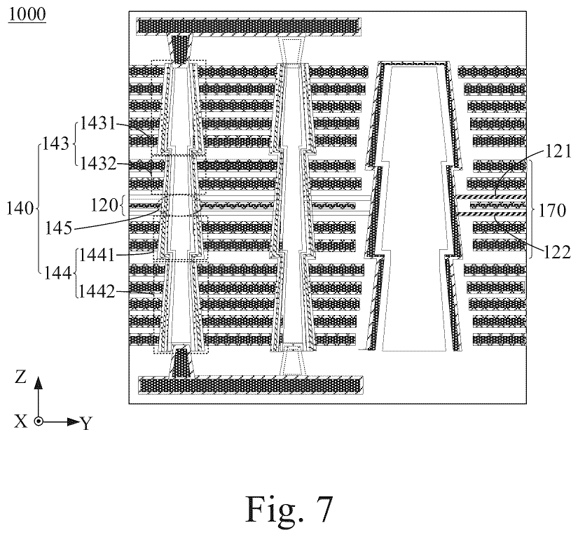

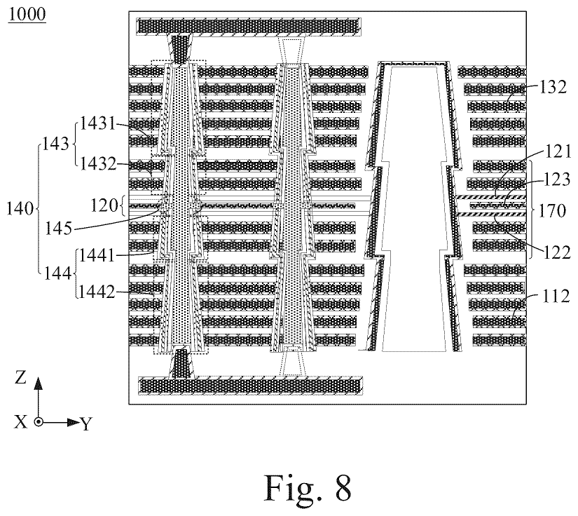

FIG. 7 is a structural diagram of another semiconductor structure 1000 provided by some implementations of the present disclosure, and FIG. 8 is a structural diagram of another semiconductor structure 1000 provided by some implementations of the present disclosure.

As shown in FIGS. 7 and 8, in some implementations, the first channel structure 143 includes the first sub-channel structure 1431 and the second sub-channel structure 1432, and the second sub-channel structure 1432 is closer to the first intermediate structure 120 compared to the first sub-channel structure 1431. The boundary of the support column of one end of the second sub-channel structure 1432 close to the redundant channel structure 145 coincides with the boundary of one end of the support column of the redundant channel structure 145. The second channel structure 144 includes the third sub-channel structure 1441 and the fourth sub-channel structure 1442, and the third sub-channel structure 1441 is closer to the first intermediate structure 120 compared to the fourth sub-channel structure 1442. The boundary of the support column of one end of the third sub-channel structure 1441 close to the redundant channel structure 145 coincides with the boundary of the other end of the support column of the redundant channel structure 145.

Since the first intermediate structure 120 is disposed in the target deck structure 170, the first source layer 121 and the second source layer 122 of the first intermediate structure 120 penetrate through the functional layer of the channel structure 140 disposed in the target deck structure 170 and are connected with the channel layer. In this way, the channel structure 140 in the target deck structure 170 is separated into the second sub-channel structure 1432, the redundant channel structure 145, and the third sub-channel structure 1441 by separating the functional layer of the channel structure 140 in the target deck structure 170.

As a feasible implementation, the support columns of the second sub-channel structure 1432, the redundant channel structure 145 and the third sub-channel structure 1441 may be obtained by the same manufacturing process. Therefore, in structure, the two ends of the support column of the redundant channel structure 145 are connected with the support column of the second sub-channel structure 1432 and the support column of the third sub-channel structure 1441 and their boundaries coincide respectively.

In addition, before manufacturing the channel structure 140, the channel hole that penetrates through the deck structure need to be manufactured in advance on each deck structure to provide space for manufacturing the channel structure 140. However, because the manufacturing of the channel hole mostly adopts etching and other processes, with the increase of the etching depth of the deck structure in the stack direction Z, the width of the manufactured channel hole will gradually decrease with the increase of the depth. This results in that the boundary of one end of the second sub-channel structure 1432 close to the third sub-channel structure 1441 is located inside the boundary of one end of the third sub-channel structure 1441 close to the second sub-channel structure 1432 in the channel structure manufactured based on the channel hole.

In addition, in the stack direction Z, the channel structure 140 disposed in the two deck structures stacked on both sides of the target deck structure 170 are the first sub-channel structure 1431 and the fourth sub-channel structure 1442 respectively. In this way, combining with the first bit line 150 and the second bit line 160 mentioned above, the first sub-channel structure 1431 and the second sub-channel structure 1432 (that is, the first channel structure 143) may read, write or erase data under the control of the first bit line 150, and the third sub-channel structure 1441 and the fourth sub-channel structure 1442 (that is, the second channel structure 144) may read, write or erase data under the control of the second bit line 160.

As a feasible implementation, the first source layer 121 may be used as the common source of the first sub-channel structure 1431 and the second sub-channel structure 1432, and the second source layer 122 may be used as the common source of the third sub-channel structure 1441 and the fourth sub-channel structure 1442. The electrical signals are provided for the operation of the channel structure 140 through the channel layer 142 of the first sub-channel structure 1431, the second sub-channel structure 1432, the third sub-channel structure 1441 and the fourth sub-channel structure 1442.

In the implementation, the distance between the sub-channel structures on both sides of the first intermediate structure 120 and their corresponding source layers may be shortened by disposing the first intermediate structure 120 in the target deck structure 170, so as to reduce the signal loss in the sub-channel structure, thereby improving the effect of the electrical connection between the sub-channel structures on both sides and their corresponding source layers, and enhancing the electrical performance of the semiconductor structure 1000.

In other examples, the first intermediate structure 120 may also be located in any one of a 3-layer stack structures which is located on both sides, and there is further no limitation on this implementation of the present disclosure.

In some other examples, the number of deck structures on both sides of the target deck structure 170 in the stack direction Z may be one or more, and there is further no limitation on this implementation of the present disclosure.

Continuing to refer to FIGS. 7 and 8, in some implementations, the boundary of one end of the first sub-channel structure 1431 close to the second sub-channel structure 1432 is located outside the boundary of one end of the second sub-channel structure 1432 close to the first sub-channel structure 1431. The boundary of one end of the third sub-channel structure 1441 close to the fourth sub-channel structure 1442 is located outside the boundary of one end of the fourth sub-channel structure 1442 close to the third sub-channel structure 1441.

In the implementation, based on the manufacturing process of the aforementioned multiple stacking technology, before manufacturing the channel structure 140, the channel hole that penetrates through the deck structure need to be manufactured in advance on each deck structure, to provide space for the manufacturing of the channel structure 140. However, because the manufacturing of the channel hole mostly adopts etching and other processes, with the increase of the etching depth of the deck structure in the stack direction Z, the width of the manufactured channel hole will gradually decrease with the increase of the depth. This results in that the aperture of one end of the first sub-channel structure 1431 close to the second sub-channel structure 1432 is smaller than the aperture of one end of the second sub-channel structure 1432 close to the first sub-channel structure 1431 in the channel structure manufactured based on the channel hole.

Similarly, the aperture of one end of the third sub-channel structure 1441 close to the fourth sub-channel structure 1442 is smaller than the aperture of one end of the fourth sub-channel structure 1442 close to the third sub-channel structure 1441.

With such configuration, the accuracy of the alignment between the channel holes of two adjacent deck structures may be improved in the multiple stacking technology, so that the effect of the electrical connection between the channel structures 140 in the two adjacent deck structures may be improved when the channel structure 140 is subsequently manufactured based on that channel hole.

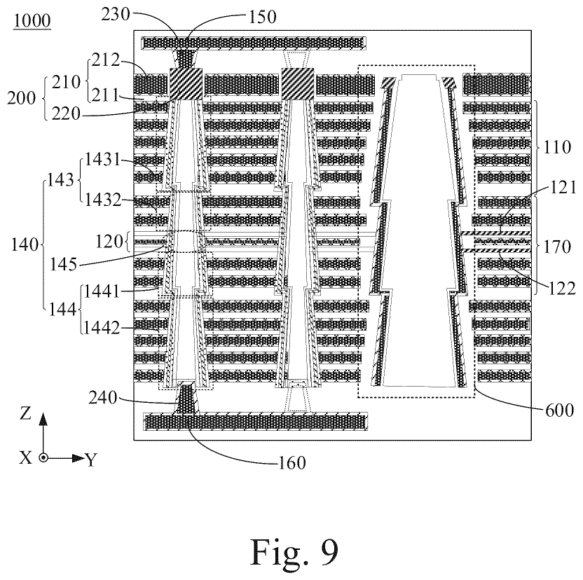

FIG. 9 is a structural diagram of another semiconductor structure 1000 provided by some implementations of the present disclosure.

As shown in FIG. 9, in some implementations, the semiconductor structure 1000 also includes a second stack structure 200. The second stack structure 200 is disposed between the first deck structure 110 and the first bit line 150, and includes the third deck structure 210 and a plurality of first connection parts 220. The third deck structure 210 includes two first dielectric layers 211 and a support layer 212, which is disposed between the two first dielectric layers 211. The first connection parts 220 penetrate through the third deck structure 210 along the stack direction Z, and the two ends of one of the first connection parts 220 are connected with one channel structure 140 and the first bit line 150 respectively.

In the implementation, the second stack structure 200 is disposed on a side of the first deck structure 110, so that the support layer 212 in the second stack structure 200 may be configured to provide support for the first deck structure 110 and even the whole first stack structure. In this way, the bending or tilting of the channel structure 140 caused by the structural stress due to the manufacturing process can be avoided during the process of manufacturing the first bit line 150, so as to ensure that the first bit line 150 manufactured subsequently may accurately align and contact with the channel structure 140, thereby improving the effect of the electrical connection of the semiconductor structure 1000 and improving the electrical performance of the semiconductor structure 1000.

In addition, a plurality of first connection parts 220 are disposed on the second stack structure 200, and the subsequent channel structure 140 is manufactured based on the first connection part 220. This may ensure the accurate docking of a plurality of channel structures 140 and the first connection part 220, and avoid that the direct manufacturing of channel structure 140 leads to the different depth of a plurality of channel structures 140 on the side close to the first bit line 150, and thereby improving the back polishing process of channel structure 140. With such configuration, the manufacturing process may be simplified, and the manufacture accuracy and the effect of the electrical connection of the semiconductor structure may be improved.

In an example, the first connection part 220 may include a conductive material, for example including, but is not limited to, W, Co, Cu, Al, doped silicon, silicide or any combination thereof. The material of the first dielectric layer 211 may include an insulating material, for example including, but is not limited to one or more of the oxide material (e.g., silicon oxide), nitride material (e.g., silicon nitride), and nitrogen oxide material (e.g., silicon oxynitride).

In an example, the materials of the support layer 212 may include materials with higher hardness, such as metal tungsten, so that the support layer 212 has good support capability.

Continuing to refer to FIG. 9, in some implementations, the semiconductor structure 1000 further includes a plurality of second connection parts 230 and a plurality of third connection parts 240. The second connection parts 230 extend along the stack direction Z. One of the second connection parts 230 is disposed between one of the first connection parts 220 and the first bit line 150, and two ends of one of the second connection parts 230 are connected with one of the first connection parts 220 and the first bit line 150 respectively. A plurality of third connection parts 240 extend along the stack direction Z. One of the third connection parts 240 is disposed between one of the channel structures 140 and the second bit line 160, and two ends of one of the third connection parts 240 are connected with one of the channel structures 140 and the second bit line 160 respectively.

In an example, by providing the plurality of second connection parts 230 and the plurality of third connection parts 240, the via contact between the first connection part 220 and the first bit line 150, and the via contact between the channel structure 140 and the second bit line 160 may be realized respectively. With such configuration, the electrical connection between the channel structure 140 and the first bit line 150 and the second bit line 160 may be realized, and at the same time, the accuracy of the docking between channel structure 140 and the first bit line 150 and the second bit line 160 may be improved. Thus, the effect of the electrical connection between channel structure 140 and the first bit line 150 and the second bit line 160 may be improved.

Both the second connection part 230 and the third connection part 240 may include conductive materials, for example, including but not limited to W, Co, Cu, Al, doped silicon, silicide or any combination thereof. The material of the second connection part 230 may be the same as or different from that of the third connection part 240. In addition, the material of the first connection part 220 may be the same as or different from those of the second connection part 230 and the third connection part 240.

In some examples, both the second connection part 230 and the third connection part 240 may include a through silicon contact (TSC), a through-silicon contact point, etc. In addition, in an example, both the second connection part 230 and the third connection part 240 may be columnar, for example, any suitable shape such as cylindrical or prismatic. Correspondingly, the shape of the cross-section of the second connection part 230 and the third connection part 240 in the first direction Z may be any shape such as a circle, an oval, a rectangle, etc.

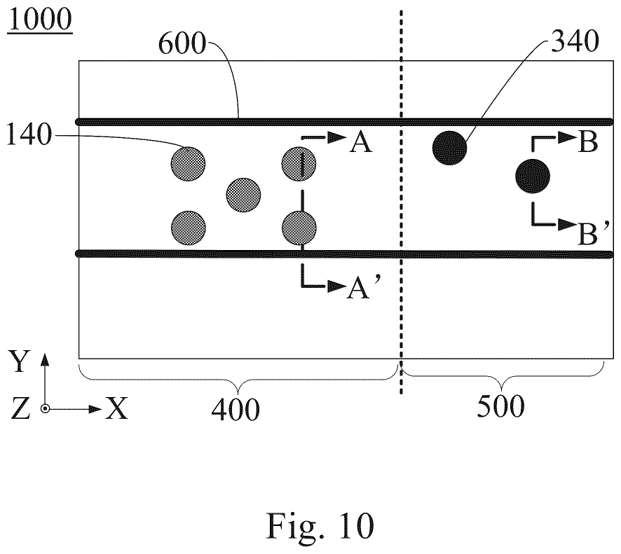

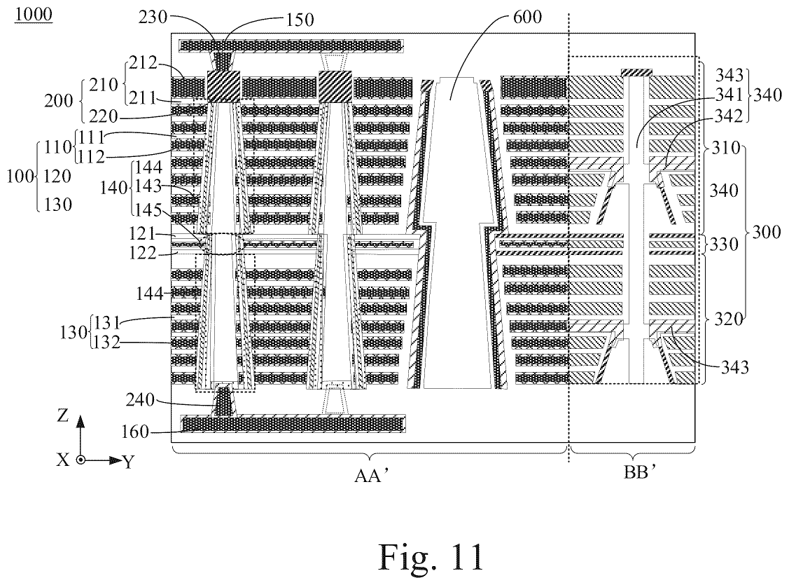

FIG. 10 is a top view diagram of a semiconductor structure 1000 provided by some implementations of the present disclosure, and FIG. 11 is a stitching diagram of the cross sections at two positions AA ‘and BB’ in FIG. 10.

As shown in FIGS. 10 and 11, in some implementations, the first deck structure 110 includes a plurality of second dielectric layers 111 and a plurality of first gate layers 112 stacked alternately, and the second deck structure 130 includes a plurality of third dielectric layers 131 and a plurality of second gate layers 132 stacked alternately. The semiconductor structure 1000 further includes a third stack structure 300. The third stack structure 300 includes the fourth deck structure 310, the fifth deck structure 320, the second intermediate structure 330, and the connection structure 340. The fourth deck structure 310 is disposed on the side of the first stack structure 100 along the second direction X, and is adjacent to the first deck structure 110 and the third deck structure 210. The fifth deck structure 320 is stacked on a side of the fourth deck structure 310, and is adjacent to the second deck structure 130. The second intermediate structure 330 is disposed between the fourth deck structure 310 and the fifth deck structure 320, and is adjacent to the first intermediate structure 120. The connection structure 340 penetrates through the fourth deck structure 310, the second intermediate structure 330 and the fifth deck structure 320 along the stack direction Z, and connects one of the first gate layers 112 and one of second gate layers 132, wherein the second direction X is perpendicular to the stack direction Z and the first direction Y.

The “stacked alternately” means that, in the manufacturing process of the stack structure, after one first material layer is formed, one second material layer is formed on the one first material layer, and then one first material layer is formed on the one second material layer, and so on . . .

Continuing to refer to FIG. 3, in the context of users pursuing large-capacity and small-size memory device, the number of stacked layers of gate lines G is increasing in order to improve the capacity of the semiconductor structure 1000. However, one of the gate lines G is connected with one of the gate line contacts G-CNT. With the increase of the number of the layers of the gate lines G, the number of the gate line contacts G-CNT coupled with the gate lines G also increases, and the area occupied by the gate line contacts G-CNT increases. As a result, the size of the semiconductor structure 1000 increases in the second direction X, which does not facilitate the improvement of the storage density of the semiconductor structure 1000 and the development of semiconductor structure 1000 towards a smaller volume.

Moreover, the gate lines G are coupled with the string drive devices through the gate line contacts G-CNT. However, one of the gate line contacts G-CNT is connected with one of the string drive devices. As the number of the gate line contacts G-CNT increases, the number of the string drive devices also increases, and the area occupied by the string drive devices also increases, which does not facilitate the development of semiconductor structure 1000 towards a smaller volume.

In the implementation, the first gate layer 112 in the first deck structure 110 and the second gate layer 132 in the second deck structure 130 may be led out by the connection structure 340 (i.e., the gate line contact G-CNT) disposed in the third stack structure 300. As a result, the channel structure 140 can read, write or erase data in the subsequent control.

With such configuration, one of the connection structures 340 may be utilized for leading out one of the first gate layers 112 and one of the second gate layers 132 together, thereby reducing the number of connection structures 340 required for the led out of the first gate layer 112 and the second gate layer 132 respectively. Especially in the case that the number of the first gate layer 112 and the second gate layer 132 are multiple, with such configuration, the number of the connection structures 340 may be greatly reduced. As a result, the area of semiconductor structure 1000 occupied by the connection structures 340 may be reduced, thereby improving the storage density of semiconductor structure 1000, and facilitating the development of semiconductor structures 1000 towards a smaller volume.

In some examples, the materials of the second dielectric layer 111 and the third dielectric layer 131 may both include insulating materials, for example, including but is not limited to one or more of oxide materials (e.g., silicon oxide), nitride material (e.g., silicon nitride), and nitrogen oxide materials (e.g., silicon oxynitride). The insulation material of the second dielectric layer 111 may be the same as or different from that of the third dielectric layer 131. The materials of the first gate layer 112 and the second gate layer 132 may both include conductive materials, for example, including but not limited to W, Co, Cu, Al, doped silicon, silicide or any combination thereof. The material of the first gate layer 112 may be the same as or different from that of the second gate layer 132.

In the implementation, the insulation materials used in the second dielectric layer 111 and the third dielectric layer 131 may both be silicon oxide, and the materials of the first gate layer 112 and the second gate layer 132 may both be tungsten (W). The second dielectric layer 111, the third dielectric layer 131, the first gate layer 112 and the second gate layer 132 all may be formed by a thin film deposition process such as chemical vapor deposition (CVD), physical vapor deposition (PVD), atomic layer deposition (ALD) or any combination thereof.

In an example, the thickness of the first gate layer 112 and the second gate layer 132 (that is, the size along the stack direction Z) may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. Similarly, the thickness of the second dielectric layer 111 and the third dielectric layer 131 (that is, the size along the stack direction Z) may be between 10 nm and 50 nm, for example, 10 nm, 15 nm, 18.3 nm, 20 nm, 25 nm, 27.7 nm, 30 nm, 35 nm, 40 nm, 45 nm, 50 nm, etc. The first gate layer 112 and the second gate layer 132 may be the gate line G around the memory string (see FIG. 3), and may extend laterally (that is, along the second direction X) as a word line WL (see FIG. 3).

Continuing to refer to FIG. 11, in some implementations, the connection structure 340 includes a connection column 341, a first connection layer 342, and a second connection layer 343. The connection column 341 penetrates through the fourth deck structure 310, the second intermediate structure 330 and the fifth deck structure 320 along the stack direction Z. The first connection layer 342 is disposed in the fourth deck structure 310, extends along the direction perpendicular to the stack direction Z, and is connected with a first gate layer 112. The second connection layer 343 is disposed in the fifth deck structure 320, extends along the direction perpendicular to the stack direction Z, and is connected with a second gate layer 132.

In the implementation, by the provided first connection layer 342 and the second connection layer 343, one of the first gate layers 112 and one of the second gate layers 132 may be led out by the connection structure 340, in turn the first connection layer 342 and the second connection layer 343 can be led out simultaneously through the connection column 341, that is, one of the first gate layers 112 and one of the second gate layers 132 is led out simultaneously.

With such configuration, the number of the connection structures 340 required to lead out the first gate layer 112 and the second gate layer 132 respectively may be reduced, so as to reduce the area of the semiconductor structure 1000 occupied by the connection structure 340, thereby improving the storage density of semiconductor structure 1000 and facilitating the development of semiconductor structure 1000 toward a smaller volume.

In an example, the constituent materials of the connection column 341, the first connection layer 342, and the second connection layer 343 may include conductive materials, which include but are not limited to one or more combinations of tungsten (W), cobalt (Co), copper (Cu), aluminum (Al), polysilicon, doped silicon, silicate, or other suitable conductive materials.

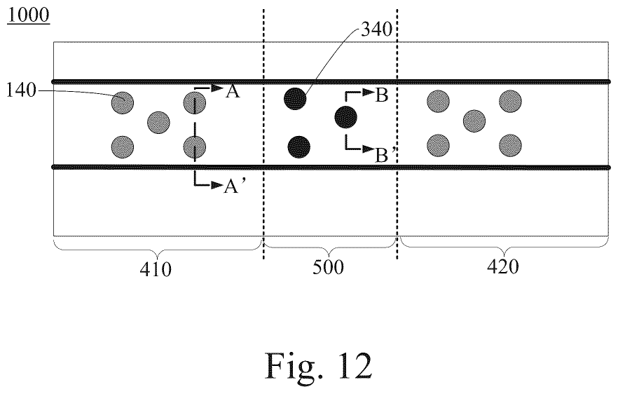

FIG. 12 is a top view diagram of other semiconductor structure 1000 provided by some implementations of the present disclosure.

As shown in FIGS. 10 and 12, in some implementations, the semiconductor structure 1000 includes a first region 400 and a second region 500. The first region 400 is adjacent to the second region 500, both the first stack structure 100 and the second stack structure 200 are located in the first region 400, and the third stack structure 300 is located in the second region 500, wherein the second region 500 is located on a side of the first region 400 in the second direction X. Alternatively, the first region 400 includes a first sub-region 410 and a second sub-region 420, which are arranged along the second direction X, and the second region 500 is located between the first sub-region 410 and the second sub-region 420.

With the above configuration, the connection structure 340 in the second region 500 may be connected with one of the first gate layers 112 and one of the second gate layers 132 in the first region 400 (or the first sub-region 410 and the second sub-region 420). With such configuration, one of the first gate layers 112 and one of the second gate layers 132 may share one connection structure 340, so as to reduce the number of connection structures 340 and the area of the second region 500 occupied by a plurality of connection structures 340, and thereby improving the storage density of the semiconductor structure 1000.

Continuing to refer to FIG. 11, in some implementations, the semiconductor structure 1000 further includes a gate line slit structure 600. The gate line slit structure 600 extends along the second direction X and penetrates through the first stack structure 100 and the second stack structure 200 along the stack direction Z. The gate line slit structure 600 is connected with the first source layer 121 and the second source layer 122, wherein the second direction X is perpendicular to the stack direction Z and the first direction Y.

In the implementation, by connecting the gate line slit structure 600 with the first source layer 121 and the second source layer 122, the first source layer 121 and the second source layer 122 may be led out with the gate line slit structure 600, in turn the electrical signal is applied to the first source layer 121 and the second source layer 122 with the gate line slit structure 600.

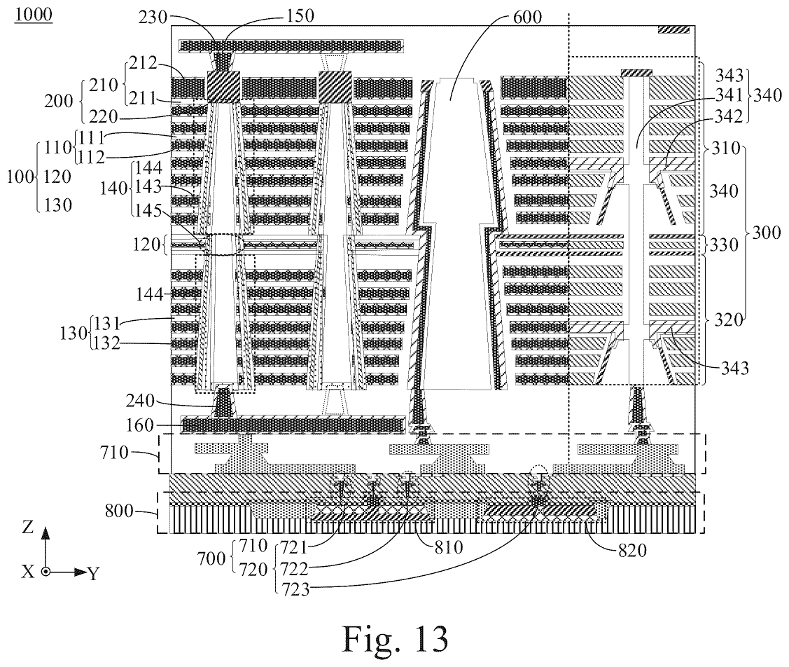

FIG. 13 is a structural diagram of another semiconductor structure 1000 provided by some implementations of the present disclosure.

As shown in FIG. 13, in some implementations, the semiconductor structure 1000 further includes interconnect layer 700, which is disposed on a side of the second bit line 160 away from the second stack structure 200. The interconnect layer 700 includes a circuit layer 710 and a plurality of interconnect structures 720, the circuit layer 710 is located between the interconnect structures 720 and the second bit line 160. The interconnect structures 720 includes the first interconnect structure 721, the second interconnect structure 722 and the third interconnect structure 723. The first interconnect structure 721 is connected to the second bit line 160 through the circuit layer 710, the second interconnect structure 722 is connected to the gate line slit structure 600 through the circuit layer 710, and the third interconnect structure 723 is connected to the connection structure 340 through the circuit layer 710.

In the implementation, the whole memory array composed of the first stack structure 100, the second stack structure 200 and the third stack structure 210 may be led out by the provided interconnect layer 700, so as to realize the transmission of the signals between the memory array and other device structures, and control the memory array of the semiconductor structure 1000 by the other device structures. The connection may include an electrical connection or a physical connection.

In an example, the circuit layer 710 may include at least one circuit structure to connect the memory array to other device structures (such as transistor structures) through its internal circuit structure (such as an interconnect wire) and interconnect structure 720. In addition, the circuit layer 710 may further include an interlayer dielectric to isolate the circuit structure, wherein the interlayer dielectrics may be made of dielectric materials, including but not limited to silicon oxide, silicon nitride, silicon oxynitride, low-k dielectrics or any combination thereof. The first interconnect structure 721, the second interconnect structure 722, and the third interconnect structure 723 may each include conductive materials, for example, including but not limited to W, Co, Cu, Al, doped silicon, silicate, or any combination thereof. The conductive materials used in the first interconnect structure 721, the second interconnect structure 722 and the third interconnect structure 723 may be same or different, and there are no limitation on this implementation of the present disclosure.

Continuing to refer to FIG. 13, in some implementations, the semiconductor structure 1000 further includes a transistor structure layer 800. The transistor structure layer 800 is disposed on a side of the interconnect layer 700 away from the second bit line 160, and the transistor structure layer 800 includes a first transistor 810 and a second transistor 820. The first electrode of the first transistor 810 is connected to the second bit line 160 through the interconnect layer 700, the second electrode of the first transistor 810 is connected to the gate line slit structure 600 through the interconnect layer 700, and the control electrode of the second transistor 820 is connected to the connection structure 340 through the interconnect layer 700. In the implementation, the transistor structure layer 800 may include a plurality of transistors T. The plurality of transistors T in the transistor structure layer 800 can be coupled with the channel structure 140 in the memory array by coupling the transistor structure layer 800 and the memory array through the interconnect layer 700, thereby realizing the transmission of the electrical signals between the transistors T and the channel structure 140, and realizing the writing, reading and erasing of data by the memory array.

Based on the semiconductor structure 1000 provided by some of the above implementations, the implementations of the present disclosure further provide a manufacturing method of the semiconductor structure 1000, which is for manufacturing the semiconductor structure 1000.

In some implementations, the manufacturing method of the semiconductor structure 1000 includes operation S1 as follows.

S1, forming a first stack structure 100. The first stack structure 100 includes a plurality of channel structures 140, and a first deck structure 110, a first intermediate structure 120 and a second deck structure 130 that are stacked, wherein the first intermediate structure 120 is stacked between the first deck structure 110 and the second deck structure 130. The channel structures 140 penetrate through the first deck structure 110, the first intermediate structure 120 and the second deck structure 130 along the stack direction Z, wherein the first intermediate structure 120 includes a first source layer 121, a second source layer 122 and an intermediate layer 123, and the intermediate layer 123 is disposed between the first source layer 121 and the second source layer 122, and the first source layer 121 and the second source layer 122 are connected with the channel structures 140 respectively.

Refer to FIG. 13, the first intermediate structure 120 is formed between the first deck structure 110 and the second deck structure 130, such that the electrical signals may be provided for the channel structure 140 in the first deck structure 110 and the second deck structure 130 respectively through the first source layer 121 and the second source layer 122 in the first intermediate structure 120. In this way, the distances between the channel structures 140 in the first deck structure 110 and the second deck structure 130 on both sides of the first intermediate structure 120 and their corresponding source layer are shortened, so as to reduce the loss of signal transmission in the channel structure 140 in the first deck structure 110 and the second deck structure 130 on both sides of the first intermediate structure 120, and in turn improve the electrical performance of the entire first stack structure 100.

In addition, the first intermediate structure 120 is formed between the first deck structure 110 and the second deck structure 130, such that the height of the first stack structure 100 may be increased by increasing the height of the first deck structure 110 and the second deck structure 130 on both sides, thereby increasing the storage capacity of the semiconductor structure 1000.

In addition, the shielding between the first source layer 121 and the second source layer 122 may be realized by the intermediate layer 123 formed in the first intermediate structure 120. As a result, the mutual interference between the first source layer 121 and the second source layer 122 may be avoided, so as to avoid the impact on the electrical performance of the first stack structure 100, and improve the stability and reliability of semiconductor structure 1000.

In some implementations, before forming the first stack structure 100, the manufacturing method of the semiconductor structure 1000 further includes operation S2 as follows.

S2, forming a second stack structure 200.

In the implementation, a second stack structure 200 is formed on a side of the first stack structure 110, such that the first stack structure 100 may be supported by the second stack structure 200. In this way, the bending or tilting of the channel structure 140 caused by the structural stress due to the manufacturing process can be avoided during the subsequent manufacturing processes, so as to ensure that the first bit line 150 manufactured subsequently may accurately align and contact with the channel structure 140, and thereby improving the effect of the electrical connection of the semiconductor structure 1000 and improving the electrical performance of the semiconductor structure 1000.

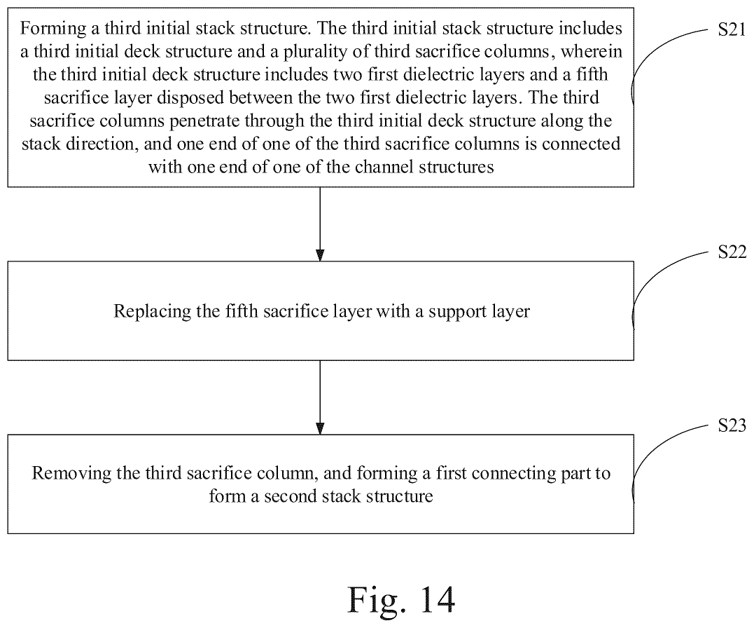

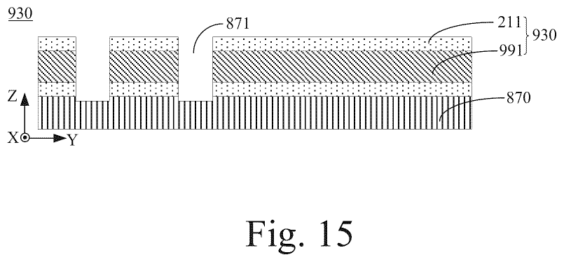

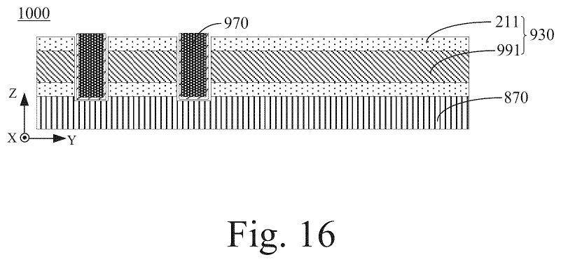

FIG. 14 is a flow chart of the manufacturing method of a second stack structure 200 provided by some implementations of the present disclosure. FIG. 15 is a structural diagram of a third initial stack structure 930 corresponding to the manufacturing method of FIG. 14. FIG. 16 is a structural diagram of a semiconductor structure 1000 corresponding to the manufacturing method of FIG. 14.

As shown in FIG. 14, the above operation S2 further includes sub-operations S21 to S23 as follows.

S21, forming a third initial stack structure. The third initial stack structure includes a third initial deck structure and a plurality of third sacrifice columns, wherein the third initial deck structure includes two first dielectric layers and a fifth sacrifice layer disposed between the two first dielectric layers. The third sacrifice columns penetrate through the third initial deck structure along the stack direction, and one end of one of the third sacrifice columns is connected with one end of one of the channel structures.

In an example, as shown in FIG. 15, a third initial deck structure 930 may be obtained by forming two first dielectric layers 211 and a fifth sacrifice layer 991 on the substrate 870 using the thin film deposition processes such as CVD, PVD, ALD, or any combination thereof, wherein the fifth sacrifice layer 991 is disposed between the two first dielectric layers 211.

In some examples, both the first dielectric layer 211 and the fifth sacrifice layer 991 may be made of insulating materials such as one or more combinations of silicon oxide, silicon nitride and high dielectric constant insulating materials, or other suitable materials. The material of the first dielectric layer 211 is different from that of the fifth sacrifice layer 991. In the implementation, for example, the material of the first dielectric layer 211 includes a silicon oxide, and the material of the fifth sacrifice layer 991 includes a silicon nitride.

Continuing to refer to FIG. 15, a photoresist is coated on a surface of a side of the manufactured third initial deck structure 930 to form a photoresist pattern, and then an etching pattern is formed on the third initial deck structure 930 using the photoresist pattern, and the third initial deck structure 930 is etched by the etching pattern, thereby obtaining a hole 871 that penetrates through the third initial deck structure 930.

In an example, the photoresist may be coated with a suitable way, such as static rotary coating, or dynamic spraying coating, etc. As an alternative, the third initial deck structure 930 may be etched by the dry etching.

As shown in FIG. 16, the insulating material may be deposited in the hole 871 by the thin film deposition processes such as CVD, PVD, ALD, or any combination thereof, to form the third sacrifice column 970, and complete the manufacturing of the third initial stack structure 990. In an example, the insulating material is, for example, one or more combinations of silicon oxide, silicon nitride and high dielectric constant insulating materials, or other suitable materials.

S22, replacing the fifth sacrifice layer with a support layer.

In an example, in this operation S22, the fifth sacrifice layer 991 may be removed with the wet etching process, and the support layer 212 is formed in the gap layer obtained after the removal of the fifth sacrifice layer 991.

As a feasible implementation, the replacement of the fifth sacrifice layer in the above operation S22 may be completed in the same process as the replacement in the subsequent manufacturing processes of the first stack structure 100, so as to simplify the manufacturing process of the semiconductor structure and reduce the manufacturing cost of the semiconductor structure.

In the implementation, for example, the material of the support layer includes a metal tungsten. By the formed support layer 212, the support of the first stack structure 100 may be realized, thereby avoiding the channel structure 140 in the first stack structure 100 from being bend or tilt due to stress in the subsequent manufacturing processes.

In other examples, the support layer may further choose some other suitable materials with a certain hardness, and there is no limitation to this implementation of the present disclosure.

S23, removing the third sacrifice column, and forming a first connection part to form a second stack structure.

In an example, in this operation S23, the third sacrifice column 970 may be removed with the wet etching process, and the conductive material may be deposited in the through hole obtained after the removal of the third sacrifice column 970, to form the first connection part 220 and complete the manufacturing of the second stack structure 200.

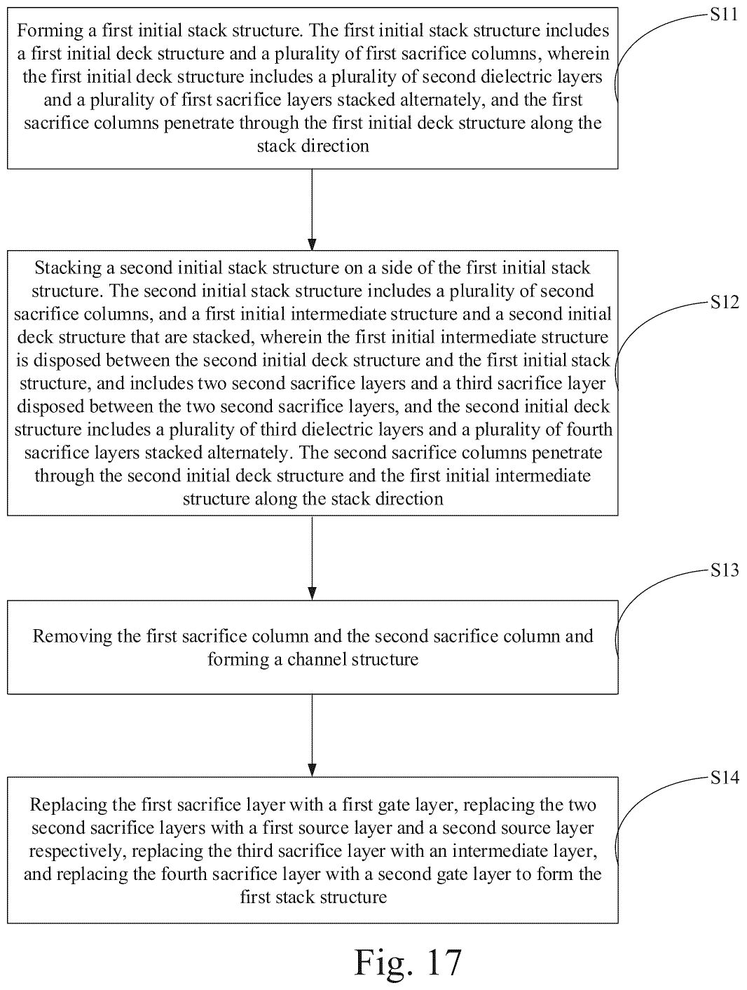

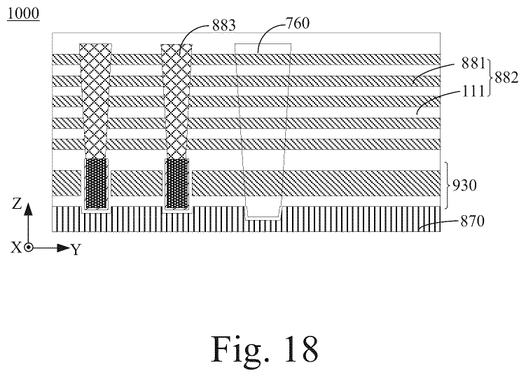

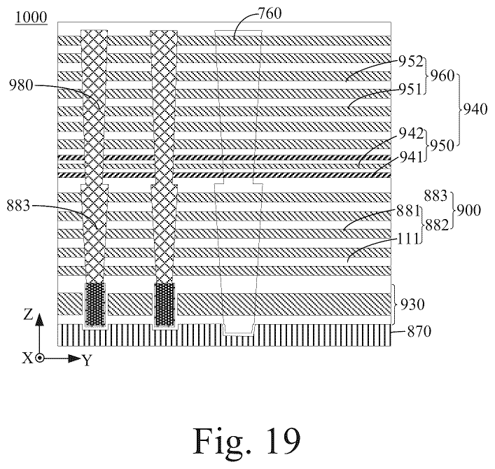

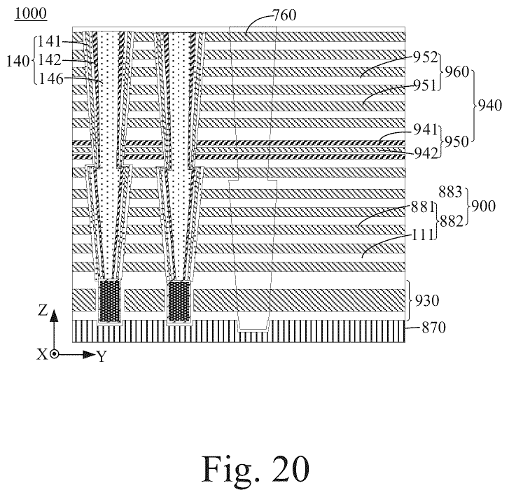

FIG. 17 is a flow chart of the manufacturing method of a first stack structure 100 provided by some implementations of the present disclosure. FIG. 18 is a structural diagram of a semiconductor structure 1000 corresponding to the manufacturing method of FIG. 17. FIG. 19 is a structural diagram of other semiconductor structure 1000 corresponding to the manufacturing method of FIG. 17. FIG. 20 is a structural diagram of another semiconductor structure 1000 corresponding to the manufacturing method in FIG. 17.

As shown in FIG. 17, in some implementations, the manufacturing method of the first stack structure 100 includes operations S11 to S14 as follows.

S11, forming the first initial stack structure. The first initial stack structure includes a first initial deck structure and a plurality of first sacrifice columns, wherein the first initial deck structure includes a plurality of second dielectric layers and a plurality of first sacrifice layers stacked alternately, and the first sacrifice columns penetrate through the first initial deck structure along the stack direction.

As shown in FIG. 18, a plurality of second dielectric layers 111 and a plurality of first sacrifice layers 881 are alternately stacked on a side of the third initial deck structure 930 away from the substrate 870 with the thin film deposition processes such as CVD, PVD, ALD, or any combination thereof, to form the first initial deck structure 882. The “stacked alternately” means that, in the manufacturing process of the first initial deck structure 882, after one second material layer 111 is formed, one first sacrifice layer 881 is formed on the one second material layer 111, and then one second material layer 111 is formed on the one first sacrifice layer 881, and so on . . .

A photoresist is coated on a surface of a side of the manufactured first initial deck structure 882 to form a photoresist pattern, and then an etching pattern is formed on the first initial deck structure 882 using the photoresist pattern, and the first initial deck structure 882 is etched by the etching pattern, to obtain the through hole that penetrates through the first initial deck structure 882.

In an example, the photoresist may be coated with a suitable way, such as static rotary coating or dynamic spraying coating, etc. As an alternative, the first initial deck structure 882 may be etched by the dry etching.

The insulating material may be deposited in the through hole by the thin film deposition processes such as CVD, PVD, ALD, or any combination thereof, to form the first sacrifice column 883, and complete the manufacturing of the first initial stack structure 900. In an example, the insulating material is, for example, one or more combinations of silicon oxide, silicon nitride and high dielectric constant insulating materials, or other suitable materials.

In this implementation, for example, the material of the second dielectric layer 111 includes silicon oxide and the material of the first sacrifice layer 881 includes silicon nitride, wherein when the material of the first dielectric layer 211 is the same as that of the second dielectric layer 111, both of them are structurally integrated, and there is no obvious boundary between them.

In some other examples, the materials of the second dielectric layer 111 and the first sacrifice layer 881 may further be other suitable materials.

S12, stacking a second initial stack structure on a side of the first initial stack structure. The second initial stack structure includes a plurality of second sacrifice columns, and a first initial intermediate structure and a second initial deck structure that are stacked, wherein the first initial intermediate structure is disposed between the second initial deck structure and the first initial stack structure, and includes two second sacrifice layers and a third sacrifice layer disposed between the two second sacrifice layers, and the second initial deck structure includes a plurality of third dielectric layers and a plurality of fourth sacrifice layers stacked alternately. The second sacrifice columns penetrate through the second initial deck structure and the first initial intermediate structure along the stack direction.

As shown in FIG. 19, in this operation S12, two second sacrifice layers 941 and a third sacrifice layer 942 may be formed on a side of the first initial stack structure 900 with the thin film deposition processes such as CVD, PVD, ALD, or any combination thereof, to form the first initial intermediate structure 950, wherein the third sacrifice layer 942 is disposed between the two second sacrifice layers 941.

A plurality of third dielectric layers 131 and a plurality of fourth sacrifice layers 952 are alternately stacked on a side of the first initial intermediate structure 950 away from the first initial stack structure 900, to form a second initial deck structure 960.

A photoresist is coated on a surface of a side of the manufactured second initial deck structure 960 to form a photoresist pattern, and then an etching pattern is formed on the second initial deck structure 960 using the photoresist pattern, and the second initial deck structure 960 and the first initial intermediate structure 950 are etched by the etching pattern, to obtain the through hole that penetrates through the second initial deck structure 960 and the first initial intermediate structure 950. The through hole exposes the first sacrifice column 883 in the first initial stack structure 900.

In an example, the photoresist may be coated with a suitable way, such as static rotary coating or dynamic spraying coating, etc. As an alternative, the second initial deck structure 960 and the first initial intermediate structure 950 may be etched by the dry etching.

The insulating material may be deposited in the through hole by the thin film deposition processes such as CVD, PVD, ALD, or any combination thereof, to form the second sacrifice column 980, and complete the manufacturing of the first second stack structure 940. In an example, the insulating material is, for example, one or more combinations of silicon oxide, silicon nitride and high dielectric constant insulating materials, or other suitable materials.

The material of the first sacrifice column 883 may be the same as or different from that of the second sacrifice column 980, and there is no limitation to the implementation of the present disclosure.

S13, removing the first sacrifice column and the second sacrifice column and forming a channel structure.

As shown in FIG. 20, the insulation material in the first sacrifice column 883 and the second sacrifice column 980 may be removed with the wet etching process, so as to obtain the through hole. A functional layer 141, a channel layer 142 and a support column 146 are successively formed in the through hole, to form a channel structure 140.

In some other examples, the first sacrifice column 883 and the second sacrifice column 980 may also be removed with other etching processes, and there is no limitation to this implementation of the present disclosure.

S14, replacing the first sacrifice layer with a first gate layer, replacing the two second sacrifice layers with a first source layer and a second source layer respectively, replacing the third sacrifice layer with an intermediate layer, and replacing the fourth sacrifice layer with a second gate layer to form the first stack structure.

Continuing to refer to FIGS. 5 and 6, in some examples, the first sacrifice layer, the second sacrifice layer, the third sacrifice layer and the fourth sacrifice layer may be removed with the wet etching process. The first gate layer 112, the first source layer 121, the second source layer 122, the intermediate layer 123 and the second gate layer 132 are formed respectively in the corresponding gap layers obtained after removing the first sacrifice layer, the second sacrifice layer, the third sacrifice layer and the fourth sacrifice layer. In this way, the manufacturing of the first deck structure 110, the first intermediate structure 120 and the second deck structure 130 is completed, and the first stack structure 100 is obtained.

In the implementation, the first stack structure 100 is manufactured by using the multiple stacking technology, which may reduce the difficulty caused by the height of the deck structure on the manufacturing processes such as etching, thereby improving the efficiency and accuracy of manufacturing the first stack structure 100, and improving the electrical performance and reliability of the semiconductor structure 1000.

In addition, the first intermediate structure 120 in the manufactured first stack structure 100 includes the first source layer 121 and the second source layer 122. The first source layer 121 and the second source layer 122 may be used as the source layers of the channel structure 140 in the first deck structure 110 and the second deck structure 130 on both sides of the first intermediate structure 120 respectively. As a result, the distance between the first deck structure 110 and the second deck structure 130 on both sides of the first intermediate structure 120 and their corresponding source layers may be shortened, thereby reducing the loss of signal transmission in the first deck structure 110 and the second deck structure 130 on both sides of the first intermediate structure 120.

With such configuration, by increasing the height of the first deck structure 110 and the second deck structure 130 on both sides, the height of the first stack structure 100 can be increased on the premise of ensuring the good electrical performance of the first stack structure 100, so as to increase the storage capacity of the first stack structure 100.

In the above implementation, the manufacturing process of the first stack structure 100 is introduced taking the number of deck structures as 2 as an example. In some other implementations, the number of deck structures may be 3, 4, 5 and other arbitrary values. In addition, in the above implementations, the first intermediate structure 120 formed between the first deck structure 110 and the second deck structure 130 is introduced as an example. In some other implementations, the first intermediate structure 120 may also be formed inside any of the deck structures, and there is no limitation to this implementation of the present disclosure.

In some implementations, prior to the above operation S14, the manufacturing method of the semiconductor structure 1000 further includes operation S130 as follows.

S130, forming a gate line slit. The gate line slit extends along the second direction, and penetrates through the first initial deck structure and the second initial deck structure along the stack direction, wherein the second direction is perpendicular to the stack direction and the first direction.

Refer to FIGS. 18 to 20, as a feasible implementation, in the aforementioned manufacturing process of manufacturing the through hole and the sacrifice column of the channel structure 140, the sacrifice trench 760 of the gate line slit may be manufactured. The material of the sacrifice trench 760 includes the insulating material, which is, for example, one or more combinations of silicon oxide, silicon nitride, and high dielectric constant insulating materials, or other suitable materials.

In some examples, the material of the sacrifice trench 760 may be the same as or different from those of the first sacrifice column 883 and the second sacrifice column 980.

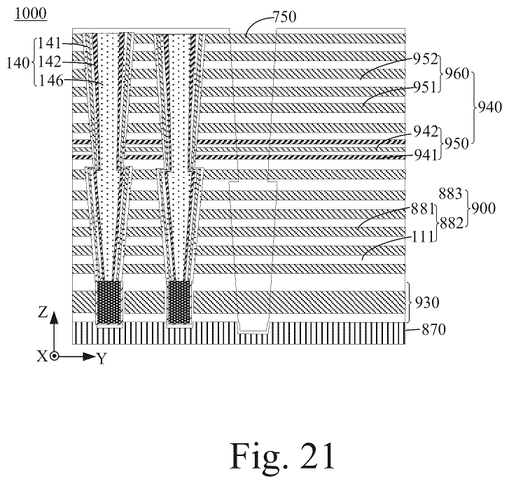

FIG. 21 is a structural diagram of another semiconductor structure 1000 provided by some implementations of the present disclosure.

As shown in FIG. 21, the sacrifice trench 760 may be removed with the wet etching process to obtain a gate line slit 750 that penetrates through the first stack structure. The gate line slit 750 extends along the second direction X, and the sidewall of the gate line slit 750 exposes the first sacrifice layer 881, the second sacrifice layer 941, the third sacrifice layer 942, and the fourth sacrifice layer 952.

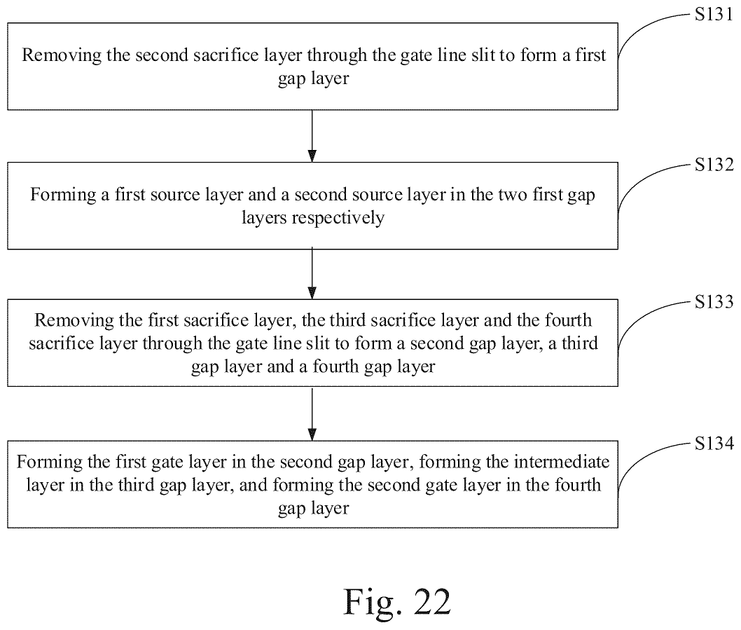

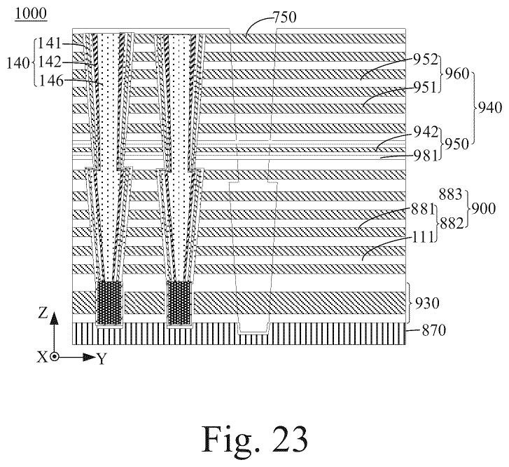

FIG. 22 is a flow chart of the manufacturing method of another first stack structure 100 provided by some implementations of the present disclosure, and FIG. 23 is a structural diagram of a semiconductor structure 1000 corresponding to the manufacturing method of FIG. 22.

As shown in FIG. 22, the above operation S130 further includes sub-operations S131 to S134 as follows.

S131, removing the second sacrifice layer through the gate line slit to form a first gap layer.

As shown in FIG. 23, because the material of the second sacrifice layer 941 is different from those of the first sacrifice layer 881, the third sacrifice layer 942 and the fourth sacrifice layer 952, the removal process of the second sacrifice layer 941 may be performed separately from those of the first sacrifice layer 881, the third sacrifice layer 942 and the fourth sacrifice layer 952.

As a feasible implementation, the second sacrifice layer 941 can be removed with the wet etching process through the gate line slit 750 to correspondingly form the first gap layer 981.

S132, forming a first source layer and a second source layer in the two first gap layers respectively.

The semiconductor material is deposited in the two first gap layers 981 with the thin film deposition processes such as CVD, PVD, ALD, or any combination thereof, to form the first source layer 121 and the second source layer 122, resulting in the semiconductor structure shown in FIG. 11. The semiconductor material may include single crystal silicon, polysilicon, single crystal germanium, group III-V compound semiconductor materials, group II-VI compound semiconductor materials, and other suitable materials.

S133, removing the first sacrifice layer, the third sacrifice layer and the fourth sacrifice layer through the gate line slit to form a second gap layer, a third gap layer and a fourth gap layer.

As a feasible implementation, the first sacrifice layer 881, the third sacrifice layer 942 and the fourth sacrifice layer 952 can be removed with the wet etching process through the gate line slit to correspondingly form the second gap layer, the third gap layer and the fourth gap layer.

S134, forming the first gate layer in the second gap layer, forming the intermediate layer in the third gap layer, and forming the second gate layer in the fourth gap layer.

In an example, the conductive material may be deposited in the second gap layer, the third gap layer, and the fourth gap layer with the thin film deposition processes such as CVD, PVD, ALD, or any combination thereof, to form the first gate layer 112, intermediate layer 123, and second gate layer 132 shown in FIGS. 5 and 6. The conductive material includes but are not limited to, W, Co, Cu, Al, doped silicon, silicide or any combination thereof.

As a feasible implementation, in the implementation, the semiconductor material used in the first source layer 121 and the second source layer 122 is polysilicon. In order to isolate the intermediate layer 123 from the first source layer 121 and the second source layer 122, one dielectric layer, such as silicon oxide, can be deposited between the conductive material of the intermediate layer 123 and the first source layer 121 and the second source layer 122 during the deposition of the intermediate layer 123. In this way, the electrical instability of the semiconductor structure caused by the direct contact of the intermediate layer 123 with the first source layer 121 and the second source layer 122 can be avoided.

In addition, in the implementation, the conductive material used in the first gate layer 112, the intermediate layer 123 and the second gate layer 132 may all be metal tungsten, and the surface of tungsten is provided with a layer of titanium nitride to prevent the diffusion of metal material, and titanium nitride has good adhesion, which facilitates the improvement of the structural stability of the intermediate layer 123.

In the implementation, a plurality of sacrifice layers may be replaced in the same manufacturing process through the gate line slit. With such configuration, the manufacturing process of the semiconductor structure 1000 may be simplified, the difficulty of the manufacturing process may be reduced, the manufacturing efficiency of the semiconductor structure 1000 may be improved, and thus the manufacturing cost may be reduced.

In some implementations, prior to operation S132 above, the manufacturing process of the semiconductor structure 1000 further includes:

Removing a portion of the channel structure 140 through two first gap layers 981 respectively to form a redundant channel structure 145.

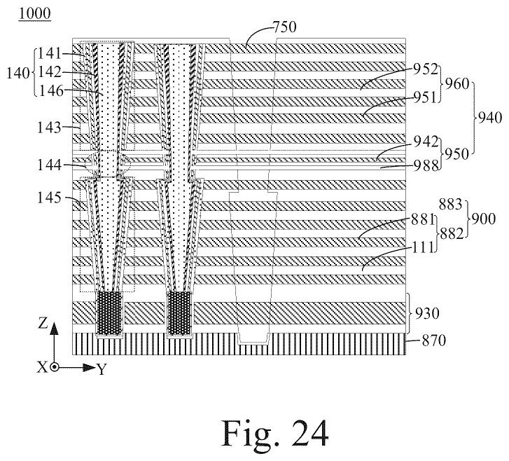

FIG. 24 is a structural diagram of a semiconductor structure 1000 corresponding to a manufacturing process provided by some implementations of the present disclosure.

As shown in FIG. 24, in an example, the functional layer 141 of channel structure 140 may be removed with the wet etching process through two first gap layers to form an eleventh gap layer 988, wherein the eleventh gap layer 988 exposes the channel layer 142 of the second channel structure 144.

With such configuration, when forming the first source layer 121 and the second source layer 122 in the subsequent manufacturing process, the first source layer 121 and the second source layer 122 may be connected with the channel layer 142, to transmit the ion in the first source layer 121 and the second source layer 122 through the channel layer 142.

Because the removal of a portion of the channel structure 140, the channel structure 140 located in the first deck structure 110 forms the first channel structure 143, and the channel structure located in the second deck structure 130 forms the second channel structure 144.

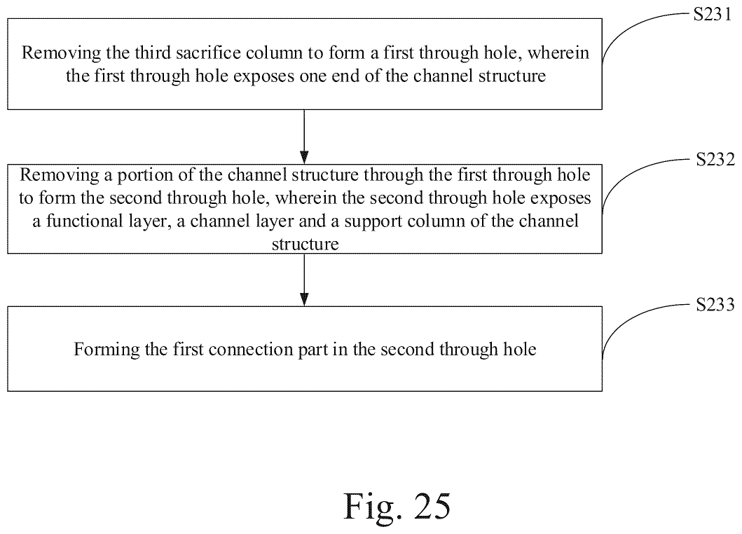

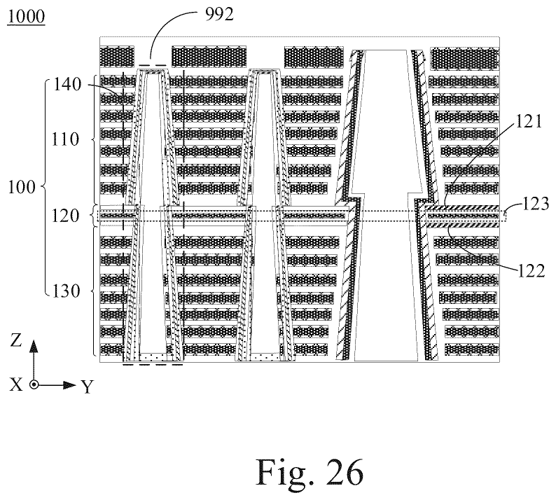

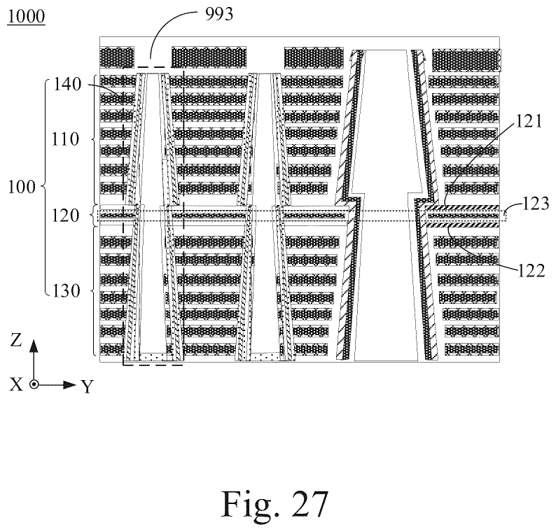

FIG. 25 is a flow chart of a manufacturing method of a first connection part 220 provided by some implementations of the present disclosure. FIG. 26 is a structural diagram of a semiconductor structure 1000 corresponding to the manufacturing method of FIG. 25. FIG. 27 is a structural diagram of another semiconductor structure 1000 corresponding to the manufacturing method of FIG. 25.

As shown in FIG. 25, the above operation S23 further includes sub-operations S231 to S233 as follows.

S231, removing the third sacrifice column to form a first through hole, wherein the first through hole exposes one end of the channel structure.

As shown in FIG. 26, in an example, in this operation S231, the third sacrifice column 970 may be removed with the wet etching process, so as to obtain the first through hole 992 that exposes the channel structure 140.

As a feasible implementation, before removing the third sacrifice column 970, the substrate on a side of the third sacrifice column 970 may be removed with a chemical mechanical polishing (CMP), and at the same time, the top surface may be planarized.

S232, removing a portion of the channel structure through the first through hole to form the second through hole, wherein the second through hole exposes a functional layer, a channel layer and a support column of the channel structure.

In an example, as shown in FIG. 27, in this operation S232, the portion of the channel structure 140 may be removed with the wet etching process through the first through hole 992, to form the second through hole 993 that exposes the functional layer 141, the channel layer 142 and the support column 146 of the channel structure 140.

S233, forming the first connection part in the second through hole.

In an example, in this operation S233, a conductive material may be deposited in the second through hole 993 with the thin film deposition processes such as CVD, PVD, ALD, or any combination thereof, to form the first connection part 220 as shown in FIG. 11.

In this implementation, by forming the first connection part 220 in the second stack structure 200, the connection between the channel structure 140 and the first bit line subsequently manufactured may be realized through the first connection part 220. With such configuration, during the manufacturing process of the channel structure 140, the depth of channel structure 140 may be limited by the first connection part 220, so that the depth of a plurality of channel structures 140 on a side close to the first bit line 150 is approximately the same. As a result, the process of polishing the back side of a plurality of channel structures 140 with different depths before the subsequent manufacturing of the first bit line 150 may be omitted, and thereby simplifying the manufacturing process of the semiconductor structure 1000.

In the above implementations, the manufacturing process of the first stack structure 100 is introduced by taking the number of deck structures being 2 and the first intermediate structure 120 being formed between the first deck structure 110 and the second deck structure 130 as an example. In the following, the manufacturing process of the first stack structure 100 is introduced by taking the number of deck structures as 3 and the first intermediate structure 120 formed in the interior of the deck structure at the middle position as an example.

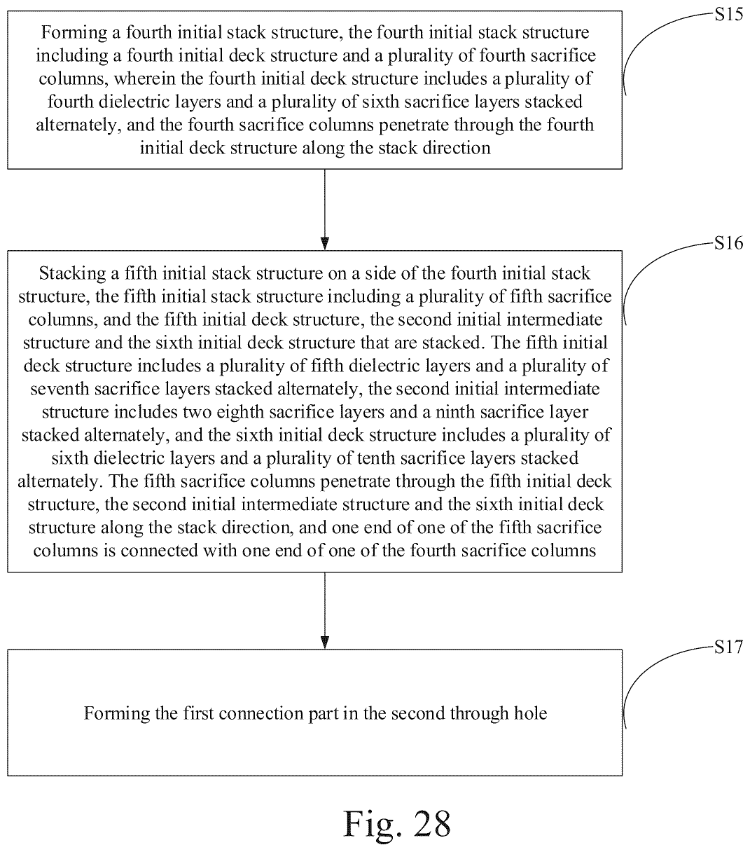

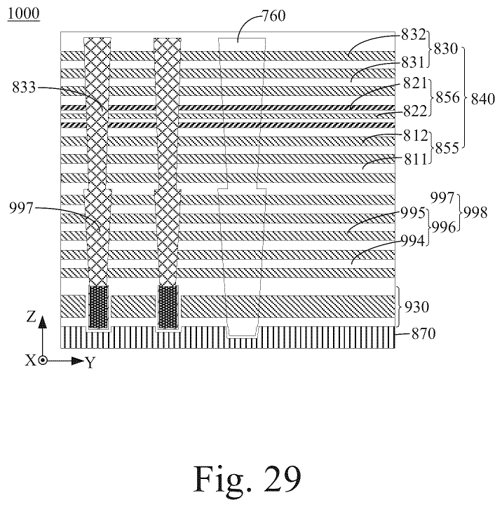

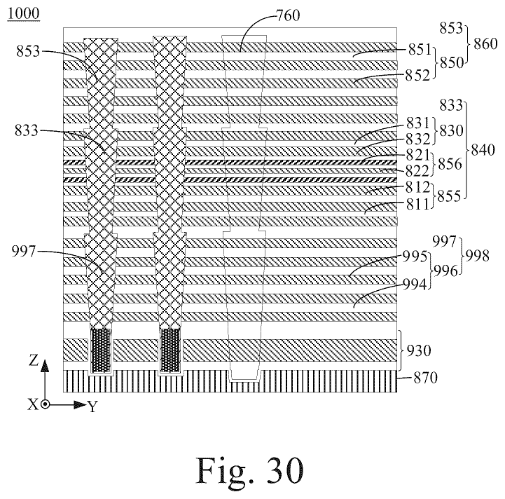

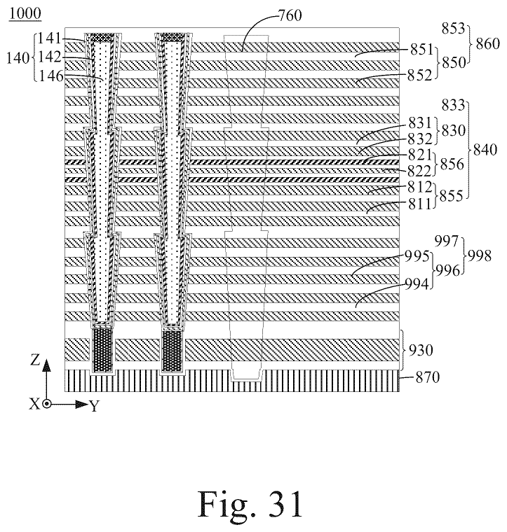

FIG. 28 is a flow chart of a manufacturing method of another first stack structure 100 provided by some implementations of the present disclosure. FIG. 29 is a structural diagram of a semiconductor structure 1000 corresponding to the manufacturing method in FIG. 28. FIG. 30 is a structural diagram of another semiconductor structure 1000 corresponding to the manufacturing method in FIG. 28. FIG. 31 is a structural diagram of other semiconductor structure 1000 corresponding to the manufacturing method in FIG. 28.

As shown in FIG. 28, in some implementations, the manufacturing method of another first stack structure 100 includes operations S15 to S19 as follows.

S15, forming a fourth initial stack structure, the fourth initial stack structure including a fourth initial deck structure and a plurality of fourth sacrifice columns, wherein the fourth initial deck structure includes a plurality of fourth dielectric layers and a plurality of sixth sacrifice layers stacked alternately, and the fourth sacrifice columns penetrate through the fourth initial deck structure along the stack direction.

As shown in FIG. 29, a plurality of fourth dielectric layers 994 and a plurality of sixth sacrifice layers 995 may be stacked alternately on a side of the third initial deck structure 930 away from the substrate 870 with the thin film deposition processes such as CVD, PVD, ALD, or any combination thereof, to form the fourth initial deck structure 996.

A photoresist is coated on a surface of a side of the manufactured fourth initial deck structure 996 to form a photoresist pattern, and then an etching pattern is formed on the fourth initial deck structure 996 using the photoresist pattern, and the fourth initial deck structure 996 is etched by the etching pattern, to obtain the through hole that penetrates through the fourth initial deck structure 996.

In an example, the photoresist may be coated with a suitable way, such as static rotary coating or dynamic spraying coating, etc. As an alternative, the fourth initial deck structure 996 may be etched by the dry etching.

The insulating material may be deposited in the through hole by the thin film deposition processes such as CVD, PVD, ALD, or any combination thereof, to form the fourth sacrifice column 997, and complete the manufacturing of the fourth initial stack structure 998. In an example, the insulating materials is, for example, one or more combinations of silicon oxide, silicon nitride and high dielectric constant insulating materials, or other suitable materials.

In an example, in this implementation, the material of the fourth dielectric layer 994 includes silicon oxide, and the material of the sixth sacrifice layer 995 includes silicon nitride. When the material of the first dielectric layer 211 is the same as that of the fourth dielectric layer 994, both of them are structurally integrated, and there is no obvious boundary between them.

S16, stacking a fifth initial stack structure on a side of the fourth initial stack structure. The fifth initial stack structure includes a plurality of fifth sacrifice columns, and the fifth initial deck structure, the second initial intermediate structure and the sixth initial deck structure that are stacked. The fifth initial deck structure includes a plurality of fifth dielectric layers and a plurality of seventh sacrifice layers stacked alternately, the second initial intermediate structure includes two eighth sacrifice layers and a ninth sacrifice layer stacked alternately, and the sixth initial deck structure includes a plurality of sixth dielectric layers and a plurality of tenth sacrifice layers stacked alternately. The fifth sacrifice columns penetrate through the fifth initial deck structure, the second initial intermediate structure and the sixth initial deck structure along the stack direction, and one end of one of the fifth sacrifice columns is connected with one end of one of the fourth sacrifice columns.

Continuing to refer to FIG. 29, in some examples, a plurality of fifth dielectric layers 811 and a plurality of seventh sacrifice layers 812 are stacked alternately on a side of the fourth initial stack structure 998 away from the third initial deck structure 930 with the thin film deposition processes such as CVD, PVD, ALD, or any combination thereof, to form a fifth initial deck structure 855.

Two eighth sacrifice layers 821 and a ninth sacrifice layer 822 are stacked alternately on a side of the fifth initial deck structure 855 away from the fourth initial stack structure 998, to form the second initial intermediate structure 856, wherein the ninth sacrifice layer 822 is disposed between the two eighth sacrifice layers 821.

A plurality of sixth dielectric layers 831 and a plurality of tenth sacrifice layers 832 are stacked alternately on a side of the second initial intermediate structure 856 away from the fifth initial deck structure 855, to form the sixth initial deck structure 830.

A photoresist is coated on a surface of a side of the manufactured sixth initial deck structure 830 to form a photoresist pattern, and then an etching pattern is on the sixth initial deck structure 830 using the photoresist pattern, and the sixth initial deck structure 830, the second initial intermediate structure 856 and the fifth initial deck structure 855 are etched by the etching pattern, to obtain the through hole that penetrates through the sixth initial deck structure 830, the second initial intermediate structure 856 and the fifth initial deck structure 855. The fourth sacrifice column 997 in the fourth initial stack structure 998 is exposed by the through hole.

In an example, the photoresist may be coated with a suitable way, such as static rotary coating or dynamic spraying coating, etc. As an alternative, the sixth initial deck structure 830, the second initial intermediate structure 856, and the fifth initial deck structure 855 may be etched by the dry etching.

The insulating material may be deposited in the through hole by the thin film deposition processes such as CVD, PVD, ALD, or any combination thereof, to form the fifth sacrifice column 833, and complete the manufacturing of the fifth initial stack structure 840. In an example, the insulating material is, for example, one or more combinations of silicon oxide, silicon nitride and high dielectric constant insulating materials, or other suitable materials.

In the implementation, the material of the fifth sacrifice column 833 may be the same as that of the fourth sacrifice column 997. In some other implementations, the material of the fifth sacrifice column 833 may be different from that of the fourth sacrifice column 997.

S17, forming a sixth initial stack structure on a side of the fifth initial stack structure away from the fourth initial stack structure, the sixth initial stack structure including the seventh initial deck structure and a plurality of sixth sacrifice columns. The seventh initial deck structure includes a plurality of seventh dielectric layers and a plurality of eleventh sacrifice layers stacked alternately. The sixth sacrifice columns penetrate through the seventh initial deck structure along the stack direction, and one end of one of the sixth sacrifice columns is connected to the other end of one of the fifth sacrifice columns.

As shown in FIG. 30, in some examples, a plurality of seventh dielectric layers 851 and a plurality of eleventh sacrifice layers 852 may be stacked alternately on a side of the fifth initial stack structure 840 away from the fourth initial stack structure 998 with the thin film deposition processes such as CVD, PVD, ALD, or any combination thereof, to form a seventh initial deck structure 850.

A photoresist is coated on a surface of a side of the manufactured seventh initial deck structure 850 to form a photoresist pattern, and then an etching pattern is formed on the seventh initial deck structure 850 using the photoresist pattern, and the seventh initial deck structure 850 is etched by the etching pattern, to obtain the through hole that penetrates through the seventh initial deck structure 850. The through hole exposes the fifth sacrifice column 833 in the fifth initial stack structure 840.

In an example, the photoresist may be coated with a suitable way, such as static rotary coating or dynamic spraying coating, etc. As an alternative, the seventh initial deck structure 850 may be etched by the dry etching.

The insulating material may be deposited in the through hole by the thin film deposition processes such as CVD, PVD, ALD, or any combination thereof, to form the sixth sacrifice column 853, and complete the manufacturing of the sixth initial stack structure 840. In an example, the insulating material is, for example, one or more combinations of silicon oxide, silicon nitride and high dielectric constant insulating materials, or other suitable materials.

In this implementation, the material of the sixth sacrifice column 853 is the same as that of the fifth sacrifice column 833.

In some other implementations, the material of the sixth sacrifice column 853 may also be different from that of the fifth sacrifice column 833.

S18, removing the fourth sacrifice column, the fifth sacrifice column, and the sixth sacrifice column, and forming a channel structure.

As shown in FIG. 31, in an example, the insulation material in the fourth sacrifice column 997, the fifth sacrifice column 833 and the sixth sacrifice column 853 may be removed with the wet etching process, to obtain the through holes. A functional layer 141, a channel layer 142 and a support column 146 are successively formed in the through hole, to form the channel structure 140.

In some other examples, the fourth sacrifice column 997, the fifth sacrifice column 833 and the sixth sacrifice column 853 may also be removed with other etching processes, and there is no limitation to the implementation of the present disclosure.

S19, replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer both with the second gate layer, to form the first stack structure.

Continuing to refer to FIGS. 7-8, in an example, the sixth sacrifice layer 995, the seventh sacrifice layer 812, the eighth sacrifice layer 821, the ninth sacrifice layer 822, the tenth sacrifice layer 832 and the eleventh sacrifice layer 852 may be removed with the wet etching process. The first gate layer 112, the first source layer 121, the second source layer 122, the intermediate layer 123 and the second gate layer 132 are formed respectively in the corresponding gap layers obtained after removing the sixth sacrifice layer 995, the seventh sacrifice layer 812, the eighth sacrifice layer 821, the ninth sacrifice layer 822, the tenth sacrifice layer 832 and the eleventh sacrifice layer 852, to complete the manufacturing of the first deck structure 110, the first intermediate structure 120 and the second deck structure 130, and obtain the first stack structure 100.

In this implementation, the first stack structure 100 is manufactured by using the multiple stacking technology, which may reduce the difficulty caused by the height of the deck structure on the manufacturing processes such as etching, thereby improving the efficiency and accuracy of manufacturing the first stack structure 100, and improving the electrical performance and reliability of the semiconductor structure 1000.

In addition, the first intermediate structure 120 in the manufactured first stack structure 100 includes the first source layer 121 and the second source layer 122. The first source layer 121 and the second source layer 122 may be used as the source layers of the channel structure 140 in the deck structures on both sides of the first intermediate structure 120 respectively. As a result, the distance between the deck structures on both sides of the first intermediate structure 120 and their corresponding source layers may be shortened, thereby reducing the loss of signal transmission in the deck structures on both sides of the first intermediate structure 120.

With such configuration, the height of the first stack structure 100 can be increased by increasing the height of the deck structures on both sides, so as to increase the storage capacity of the first stack structure 100 on the premise of ensuring the good electrical performance of the first stack structure 100.

In some implementations, prior to operation S19 above, the manufacturing method of the semiconductor structure 1000 further includes the operation S190 as follows:

S190, forming a gate line slit. The gate line slit extends along the second direction, and penetrates through the fourth initial stack structure, the fifth initial stack structure and the sixth initial stack structure along the stack direction, wherein the second direction is perpendicular to the stack direction and the first direction.

Refer to FIGS. 29-31, as a feasible implementation, in the aforementioned manufacturing process of manufacturing the through hole and the sacrifice column of the channel structure 140, the sacrifice trench 760 of the gate line slit may be manufactured. The material of the sacrifice trench 760 includes the insulating material, which is, for example, one or more combinations of silicon oxide, silicon nitride and high dielectric constant insulating materials, or other suitable materials.

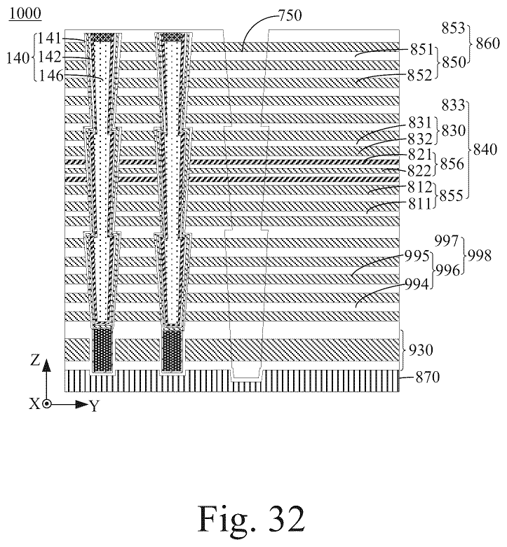

FIG. 32 is a structural diagram of other semiconductor structure 1000 corresponding to the manufacturing process provided by some implementations of the present disclosure. As shown in FIG. 32, the sacrifice trench 760 may be removed with the wet etching process to obtain a gate line slit 750 that penetrates through the first stack structure. The gate line slit 750 extends along the second direction X, and the sidewall of the gate line slit 750 exposes the sixth sacrifice layer 995, the seventh sacrifice layer 812, the eighth sacrifice layer 821, the ninth sacrifice layer 822, the tenth sacrifice layer 832 and the eleventh sacrifice layer 852.

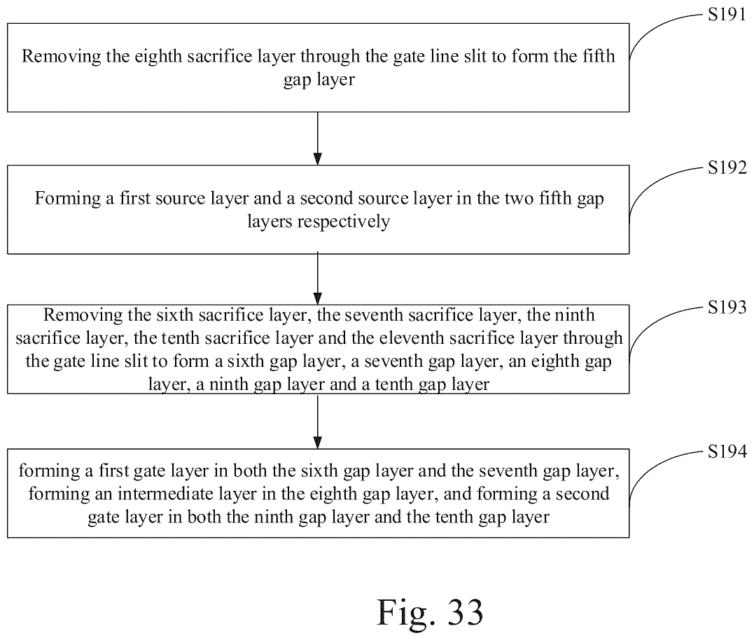

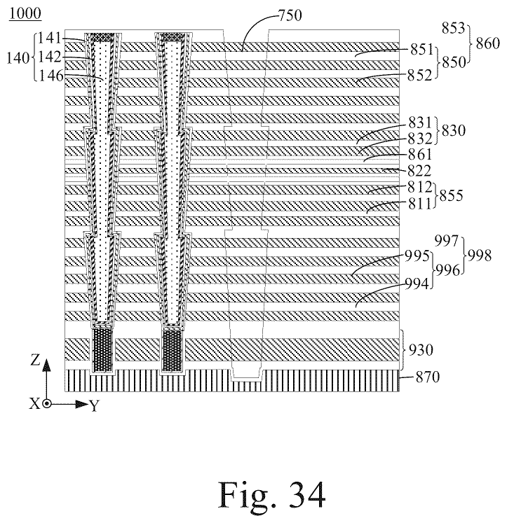

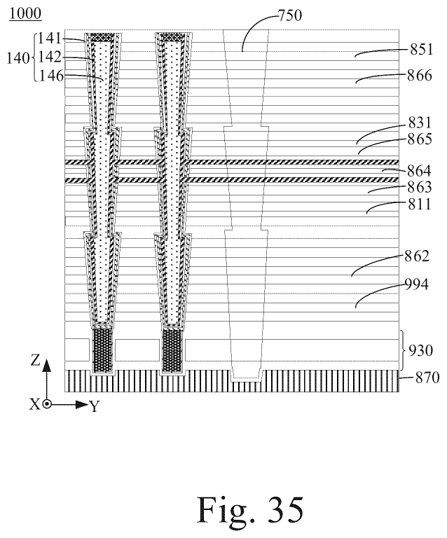

FIG. 33 is a flow chart of a manufacturing method of another first stack structure 100 provided by some implementations of the present disclosure. FIG. 34 is a structural diagram of a semiconductor structure 1000 corresponding to the manufacturing method in FIG. 33. FIG. 35 is a structural diagram of a semiconductor structure 1000 corresponding to the manufacturing method in FIG. 33.

As shown in FIG. 33, the above operations S19 further include the sub-operations S191 to S194 as follows.

S191, removing the eighth sacrifice layer through the gate line slit to form the fifth gap layer.

Since the material of the eighth sacrifice layer 821 is different from those of the sixth sacrifice layer 995, the seventh sacrifice layer 812, the ninth sacrifice layer 822, the tenth sacrifice layer 832 and the eleventh sacrifice layer 852, the removal process of the eighth sacrifice layer 821 may be performed separately from the removal processes of the sixth sacrifice layer 995, the seventh sacrifice layer 812, the ninth sacrifice layer 822, the tenth sacrifice layer 832 and the eleventh sacrifice layer 852.

As shown in FIGS. 32 and 34, as a feasible implementation, the eighth sacrifice layer 821 can be removed with the wet etching process through the gate line slit 750, to correspondingly form two fifth gap layers 861.

S192, forming a first source layer and a second source layer in the two fifth gap layers respectively.

The semiconductor material is deposited in the two fifth gap layers 861 with the thin film deposition processes such as CVD, PVD, ALD, or any combination thereof, to form the first source layer 121 and the second source layer 122. The semiconductor material may include single crystal silicon, polysilicon, single crystal germanium, group III-V compound semiconductor materials, group II-VI compound semiconductor materials, and other suitable materials.

S193, removing the sixth sacrifice layer, the seventh sacrifice layer, the ninth sacrifice layer, the tenth sacrifice layer and the eleventh sacrifice layer through the gate line slit to form a sixth gap layer, a seventh gap layer, an eighth gap layer, a ninth gap layer and a tenth gap layer.

As shown in FIGS. 32 and 35, as a feasible implementation, the sixth sacrifice layer 995, the seventh sacrifice layer 812, the ninth sacrifice layer 822, the tenth sacrifice layer 832 and the eleventh sacrifice layer 852 can be removed with the wet etching process through the gate line slit, to correspondingly form the sixth gap layer 862, the seventh gap layer 863, the eighth gap layer 864, the ninth gap layer 865 and the tenth gap layer 866.

S194, forming a first gate layer in both the sixth gap layer and the seventh gap layer, forming an intermediate layer in the eighth gap layer, and forming a second gate layer in both the ninth gap layer and the tenth gap layer.

In an example, the conductive material may be deposited in the sixth gap layer 862, seventh gap layer 863, eighth gap layer 864, ninth gap layer 865 and tenth gap layer 866 with the thin film deposition processes such as CVD, PVD, ALD, or any combination thereof, to form the first gate layer 112, the intermediate layer 123, and the second gate layer 132 as shown in FIGS. 7 and 8. The conductive material includes but are not limited to, W, Co, Cu, Al, doped silicon, silicide or any combination thereof.

As a feasible implementation, in the implementation, the semiconductor material used in the first source layer 121 and the second source layer 122 is polysilicon. In order to isolate the intermediate layer 123 from the first source layer 121 and the second source layer 122, one dielectric layer, such as silicon oxide, can be deposited between the conductive material of the intermediate layer 123 and the first source layer 121 and the second source layer 122 during the deposition of the intermediate layer 123. In this way, the electrical instability of the semiconductor structure caused by the direct contact of the intermediate layer 123 with the first source layer 121 and the second source layer 122 can be avoided.

In addition, in the implementation, the conductive material used in the first gate layer 112, the intermediate layer 123 and the second gate layer 132 may all be metal tungsten, and the surface of tungsten is provided with a layer of titanium nitride to prevent the diffusion of metal material, and titanium nitride has good adhesion, which facilitates the improvement of the structural stability of the intermediate layer 123.

In this implementation, a plurality of sacrifice layers may be replaced in the same manufacturing process through the gate line slit. With such configuration, the manufacturing process of the semiconductor structure 1000 may be simplified, the difficulty of the manufacturing process may be reduced, the manufacturing efficiency of the semiconductor structure 1000 may be improved, and thus the manufacturing cost may be reduced.

In some implementations, prior to operation S192 above, the manufacturing process of the semiconductor structure 1000 further includes:

Removing a portion of the channel structure 140 through two eighth gap layers 864 respectively to form the redundant channel structure 145.

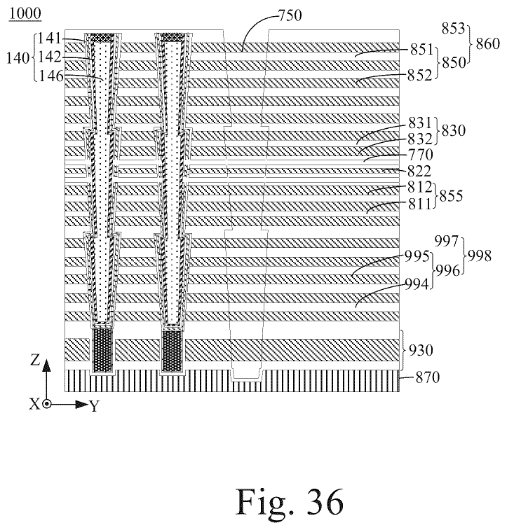

FIG. 36 is a structural diagram of another semiconductor structure 1000 corresponding to a manufacturing process provided by some implementations of the present disclosure.

As shown in FIG. 36, in an example, the functional layer 141 of channel structure 140 may be removed with the wet etching process through two fifth gap layers 861 to form a twelfth gap layer 770, wherein the twelfth gap layer 770 exposes the channel layer 142 of channel structure 140.

With such configuration, when forming the first source layer 121 and the second source layer 122 in the subsequent manufacturing process, the first source layer 121 and the second source layer 122 may be connected with the channel layer 142, to transmit the ion in the first source layer 121 and the second source layer 122 through the channel layer 142.

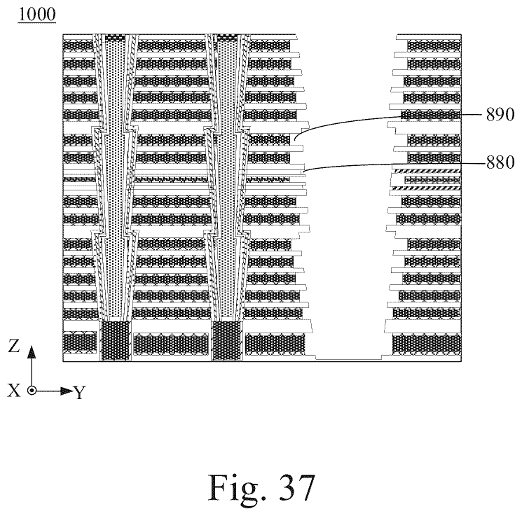

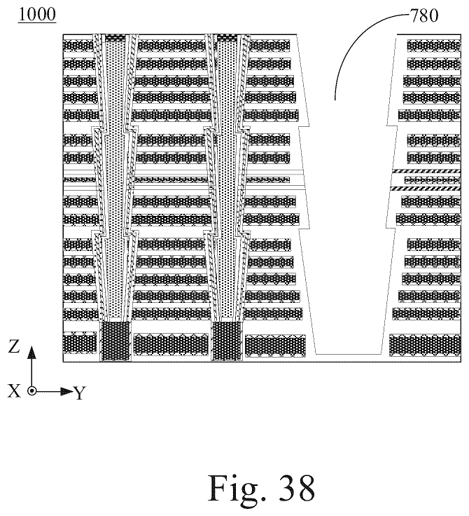

FIG. 37 is a structural diagram of another semiconductor structure 1000 corresponding to the manufacturing process provided by some implementations of the present disclosure, and FIG. 38 is a structural diagram of another semiconductor structure 1000 corresponding to the manufacturing process provided by some implementations of the present disclosure.

In some implementations, the manufacturing method of the semiconductor structure 1000 further includes operation S3 as follows.

S3, forming a gate line slit structure in the gate line slit. The gate line slit structure is connected to both the first source layer and the second source layer.

In this operation S3, by forming the gate line slit structure in the gate line slit, the first source layer and the second source layer may be led out using the gate line slit structure.

In an example, as shown in FIG. 37, when filling the first source layer and the second source layer in the preceding operation S192, the filled semiconductor material will cover the side wall of the gate line slit. In order to avoid affecting the subsequent sacrifice layer replacement process, the semiconductor material on the side wall of the gate line slit may be removed by the dry etching process or wet etching process. In the actual manufacturing process, during the process of removing the semiconductor material on the side wall of the gate line slit, the portions of the first source layer and the second source layer are removed together to form the first groove 880.

In addition, during the replacement of a plurality of sacrifice layers in operation S193 above, some metal material (e.g., tungsten) will be covered on the side wall of the gate line slit. The metal material on the side wall of the gate line slit may be removed by the dry etching process or wet etching process, to avoid affecting the subsequent manufacturing of the gate line slit structure. In the actual manufacturing process, during the process of removing the gate material on the side wall of the gate line slit, the portions of the gate layer and the support layer will be removed together to form the second groove 890.

The depth of the second groove 890 in the first direction Y is larger than the depth of the first groove 880 in the first direction Y.

With such configuration, the thickness of the insulating layer at the corresponding positions of the first source layer and the second source layer may be thinner than the thickness of the insulating layer at the corresponding positions of the gate layer and the support layer in the subsequent process of forming the insulating layer by deposition of the insulation material through the gate line slit. In an example, the insulating layer may realize the insulation between the gate line slit structure and a plurality of gate layers in the subsequent process of manufacturing the gate line slit structure.

As shown in FIG. 38, in some examples, a portion of the insulating layer may be removed with the etching process in the subsequent manufacturing process, to form a strip slot 780, wherein the strip slot 780 may expose at least portion of the first source layer and second source layer, such that in the subsequent manufacturing of the gate line slit structure based on the strip slot 780, the first source layer and the second source layer may be connected to the gate line slit structure, and the first source layer and the second source layer may be led out through the gate line slit structure.

Because the thickness of the insulating layer is thick at the corresponding positions of the gate layer and the support layer, after removing a portion of the insulating layer, the remaining insulating layer may cover a plurality of gate layers and support layers on the premise of exposing the first source layer and the second source layer. In this way, the subsequent formation of the gate line slit structure 600 is prevented from contacting with the gate layer or support layer, which affects the electrical performance of the semiconductor structure.

In an example, the conductive material, the insulating material and the semiconductor material may be sequentially deposited in the strip slot 780 by the thin film deposition processes such as CVD, PVD, ALD, or any combination thereof, to form a conductive structure, a support structure, and an insulating structure between them, thereby forming the gate line slit structure 600 as shown in FIG. 9. The first source layer and the second source layer are connected with the conductive structure. With such configuration, the first source layer and the second source layer may be led out through the conductive structure, which facilitates simplifying the control of the semiconductor structure.

The above is only the implementations of the present disclosure, but the scope of protection of the present disclosure is not limited to this. Any change or substitution that can be easily thought of by those skilled in the art familiar with the technical field in the technical scope disclosed in this disclosure should be covered by the scope of protection of the present disclosure. Therefore, the scope of protection of the present disclosure should be subject to the scope of protection of the appended claims.

What is claimed is:

1. A semiconductor structure, comprising:
a first stack structure, comprising:
a plurality of channel structures, and
a first deck structure, a first intermediate structure and a second deck structure that are stacked, wherein the first intermediate structure is stacked between the first deck structure and the second deck structure, and the channel structures extend through the first deck structure, the first intermediate structure and the second deck structure along a stack direction, and
wherein the first intermediate structure comprises:
a first source layer;
a second source layer; and
an intermediate layer disposed between the first source layer and the second source layer, wherein the first source layer and the second source layer are connected with the channel structures respectively.

2. The semiconductor structure of claim 1, wherein the intermediate layer comprises:
a first insulating layer;
a conductive layer; and
a second insulating layer, wherein the conductive layer is disposed between the first insulating layer and the second insulating layer.

3. The semiconductor structure of claim 1, further comprising:
a first bit line disposed on a side of the first deck structure away from the first intermediate structure, wherein the first bit line extends along a first direction, and is connected with one end of a row of the channel structures, and wherein the first direction is perpendicular to the stack direction; and
a second bit line disposed on a side of the second deck structure away from the first intermediate structure, wherein the second bit line extends along the first direction, and is connected with the other end of the row of the channel structures.

4. The semiconductor structure of claim 3, wherein the channel structure comprises:
a functional layer; and
a channel layer which the functional layer surrounds; and
wherein the channel structure further comprises:
a first channel structure disposed at the first deck structure, and extending through the first deck structure along the stack direction, wherein one end of the first channel structure is connected with the first bit line, and the function layer and the channel layer at the other end of the first channel structure are connected with the first source layer;
a second channel structure disposed at the second deck structure, and extending through the second deck structure along the stack direction, wherein one end of the second channel structure is connected with the second bit line, and the function layer and the channel layer at the other end of the second channel structure are connected with the second source layer; and
a redundant channel structure disposed between the first deck structure and the second deck structure, wherein the redundant channel structure extends along the stack direction, and one end of the redundant channel structure is connected with the first channel structure, and the other end of the redundant channel structure is connected with the second channel structure.

5. The semiconductor structure of claim 4, wherein:
the channel structure further comprises a support column which the function layer and the channel layer surround, and wherein the channel layer is located between the function layer and the support column; and
two ends of the support column of the redundant channel structure extend into the first source layer and the second source layer respectively, wherein one end of the support column of the redundant channel structure is connected with the support column of the first channel structure, the other end of the support column of the redundant channel structure is connected with the support column of the second channel structure, and the functional layer of the redundant channel structure is in contact with the intermediate layer.

6. The semiconductor structure of claim 4, wherein:
the channel structure further comprises a support column which the function layer and the channel layer surround, and wherein the channel layer is located between the function layer and the support column;
two ends of the support column of the redundant channel structure extend into the first source layer and the second source layer respectively, wherein one end of the support column of the redundant channel structure is connected with the support column of the first channel structure, the other end of the support column of the redundant channel structure is connected with the support column of the second channel structure, and wherein a portion of the support column of the redundant channel structure extends through the channel layer and the functional layer along a direction perpendicular to the stack structure, and is in contact with the intermediate layer; and
the portion of the support column of the redundant channel structure that extends through the channel layer and the functional layer is a set support column, and boundaries of the set support column are all in contact with the intermediate layer.

7. The semiconductor structure of claim 5, wherein:
the first channel structure comprises:
a first sub-channel structure; and
a second sub-channel structure, wherein the second sub-channel structure is closer to the first intermediate structure than the first sub-channel structure, and a boundary of the support column of one end of the second sub-channel structure close to the redundant channel structure coincides with a boundary of one end of the support column of the redundant channel structure;
the second channel structure comprises:
a third sub-channel structure; and
a fourth sub-channel structure, wherein the third sub-channel structure is closer to the first intermediate structure than the fourth sub-channel structure, and a boundary of the support column of one end of the third sub-channel structure close to the redundant channel structure coincides with a boundary of the other end of the support column of the redundant channel structure.

8. The semiconductor structure of claim 7, wherein the semiconductor structure further comprises:
a second stack structure disposed between the first deck structure and the first bit line, wherein the second stack structure comprises a third deck structure and a plurality of first connection parts, and
wherein the third deck structure comprises two first dielectric layers and a support layer disposed between the two first dielectric layers; and
wherein the first connection parts extend through the third deck structure along the stack direction, and two ends of one of the first connection parts are connected with one of the channel structures and the first bit line respectively.

9. The semiconductor structure of claim 1, wherein:
the first deck structure comprises a plurality of second dielectric layers and a plurality of first gate layers alternately stacked, and the second deck structure comprises a plurality of third dielectric layers and a plurality of second gate layers alternately stacked; and
the semiconductor structure further comprises a third stack structure, comprising:
a fourth deck structure disposed on a side of the first stack structure along a second direction, and is adjacent to both the first deck structure and the third deck structure;
a fifth deck structure stacked on a side of the fourth deck structure and is adjacent to the second deck structure;
a second intermediate structure disposed between the fourth deck structure and the fifth deck structure and is adjacent to the first intermediate structure; and
a connection structure extending through the fourth deck structure, the second intermediate structure and the fifth deck structure along the stack direction, and is connected to one of the first gate layers and one of the second gate layers,
wherein the second direction is perpendicular to the stack direction and the first direction.

10. The semiconductor structure of claim 9, wherein the connection structure comprises:
a connection column extending through the fourth deck structure, the second intermediate structure and the fifth deck structure along the stack direction;
a first connection layer disposed in the fourth deck structure, wherein the first connection layer extends along a direction perpendicular to the stack direction, and is connected with one of the first gate layers; and
a second connection layer disposed in the fifth deck structure, wherein the second connection layer extends along a direction perpendicular to the stack direction, and is connected with one of the second gate layers.

11. A manufacturing method of semiconductor structure, comprising:
forming a first stack structure comprising a plurality of channel structures, and a first deck structure, a first intermediate structure and a second deck structure that are stacked,
wherein the first intermediate structure is stacked between the first deck structure and the second deck structure, and the channel structures extend through the first deck structure, the first intermediate structure and the second deck structure along a stack direction, and
wherein the first intermediate structure comprises a first source layer, a second source layer and an intermediate layer, and wherein the intermediate layer is disposed between the first source layer and the second source layer, and the first source layer and the second source layer are connected with the channel structures respectively.

12. The manufacturing method of semiconductor structure of claim 11, wherein the forming the first stack structure comprises:
forming a first initial stack structure comprising a first initial deck structure and a plurality of first sacrifice columns, wherein the first initial deck structure comprises a plurality of second dielectric layers and a plurality of first sacrifice layers stacked alternately, and the first sacrifice columns extend through the first initial deck structure along the stack direction;
stacking a second initial stack structure on a side of the first initial stack structure, the second initial stack structure comprising a plurality of second sacrifice columns, and a first initial intermediate structure and a second initial deck structure that are stacked, wherein the first initial intermediate structure is disposed between the second initial deck structure and the first initial stack structure, and comprises two second sacrifice layers and a third sacrifice layer disposed between the two second sacrifice layers, and wherein the second initial deck structure comprises a plurality of third dielectric layers and a plurality of fourth sacrifice layers stacked alternately, and wherein the second sacrifice columns extend through the second initial deck structure and the first initial intermediate structure along the stack direction;
removing the first sacrifice columns and the second sacrifice columns and forming the channel structures; and
replacing the first sacrifice layer with a first gate layer, replacing the two second sacrifice layers with the first source layer and the second source layer respectively, replacing the third sacrifice layer with the intermediate layer, and replacing the fourth sacrifice layer with a second gate layer, to form the first stack structure.

13. The manufacturing method of semiconductor structure of claim 12, further comprises:
before replacing the first sacrifice layer with the first gate layer, replacing the two second sacrifice layers with the first source layer and the second source layer respectively, replacing the third sacrifice layer with the intermediate layer, and replacing the fourth sacrifice layer with the second gate layer,
forming a gate line slit extending along a second direction and extending through the first initial deck structure and the second initial deck structure along the stack direction, wherein the second direction is perpendicular to the stack direction and the first direction; and
wherein the replacing the first sacrifice layer with the first gate layer, replacing the two second sacrifice layers with the first source layer and the second source layer respectively, replacing the third sacrifice layer with the intermediate layer, and replacing the fourth sacrifice layer with the second gate layer, comprises:
removing the second sacrifice layers through the gate line slit to form first gap layers;
forming the first source layer and the second source layer in two of the first gap layers respectively;
removing the first sacrifice layer, the third sacrifice layer and the fourth sacrifice layer through the gate line slit to form a second gap layer, a third gap layer and a fourth gap layer; and
forming the first gate layer in the second gap layer, forming the intermediate layer in the third gap layer, and forming the second gate layer in the fourth gap layer.

14. The manufacturing method of semiconductor structure of claim 13, further comprises:
before forming the first source layer and the second source layer in two of the first gap layers respectively,
removing a portion of the channel structure through two of the first gap layers respectively, to form a redundant channel structure.

15. The manufacturing method of semiconductor structure of claim 14, further comprises: before forming the first stack structure,
forming a second stack structure, comprising:
forming a third initial stack structure comprising a third initial deck structure and a plurality of third sacrifice columns, wherein the third initial deck structure comprises two first dielectric layers and a fifth sacrifice layer disposed between the two first dielectric layers, and wherein the third sacrifice columns extend through the third initial deck structure along the stack direction, and one end of one of the third sacrifice columns is connected with one end of one of the channel structures;
replacing the fifth sacrifice layer with a support layer; and
removing the third sacrifice column and forming a first connection part, to form the second stack structure.

16. The manufacturing method of semiconductor structure of claim 15, wherein the removing the third sacrifice column and forming the first connection part comprises:
removing the third sacrifice column to form a first through hole, wherein the first through hole exposes one end of the channel structure;
removing a portion of the channel structure through the first through hole to form a second through hole, wherein the second through hole exposes a functional layer, a channel layer and a support column of the channel structure; and
forming the first connection part in the second through hole.

17. The manufacturing method of semiconductor structure of claim 11, wherein the forming the first stack structure comprises:
forming a fourth initial stack structure comprising a fourth initial deck structure and a plurality of fourth sacrifice columns, wherein the fourth initial deck structure comprises a plurality of fourth dielectric layers and a plurality of sixth sacrifice layers stacked alternately, and the fourth sacrifice columns extend through the fourth initial deck structure along the stack direction;
stacking a fifth initial stack structure on a side of the fourth initial stack structure, the fifth initial stack structure comprising a plurality of fifth sacrifice columns, and a fifth initial deck structure, a second initial intermediate structure and a sixth initial deck structure that are stacked, wherein the fifth initial deck structure comprises a plurality of fifth dielectric layers and a plurality of seventh sacrifice layers stacked alternately, and the second initial intermediate structure comprises two eighth sacrifice layers and a ninth sacrifice layer disposed between the two eighth sacrifice layers, and the sixth initial deck structure comprises a plurality of sixth dielectric layers and a plurality of tenth sacrifice layers stacked alternately, and wherein the fifth sacrifice columns extend through the fifth initial deck structure, the second initial intermediate structure and the sixth initial deck structure along the stack direction, and one end of one of the fifth sacrifice columns is connected with one end of one of the fourth sacrifice columns;
forming a sixth initial stack structure on a side of the fifth initial stack structure away from the fourth initial stack structure, the sixth initial stack structure comprising a seventh initial deck structure and a plurality of sixth sacrifice columns, wherein the seventh initial deck structure comprises a plurality of seventh dielectric layers and a plurality of eleventh sacrifice layers stacked alternately, and wherein the sixth sacrifice columns extend through the seventh initial deck structure along the stack direction, and one end of one of the sixth sacrifice columns is connected to the other end of one of the fifth sacrifice columns;
removing the fourth sacrifice column, the fifth sacrifice column, and the sixth sacrifice column, and forming the channel structure; and
replacing the sixth sacrifice layer and the seventh sacrifice layer both with a first gate layer, replacing the eighth sacrifice layer with the intermediate layer, replacing the two ninth sacrifice layers with the first source layer and the second source layer respectively, and replacing the tenth sacrifice layer and the eleventh sacrifice layer both with a second gate layer, to form the first stack structure.

18. The manufacturing method of semiconductor structure of claim 17, further comprises:
before the replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer with the second gate layer, forming a gate line slit extending along a second direction and extending through the fourth initial stack structure, the fifth initial stack structure and the sixth initial stack structure along the stack direction, wherein the second direction is perpendicular to the stack direction and the first direction; and
wherein the replacing the sixth sacrifice layer and the seventh sacrifice layer both with the first gate layer, replacing the eighth sacrifice layer with the intermediate layer, replacing the two ninth sacrifice layers with the first source layer and the second source layer respectively, and replacing the tenth sacrifice layer and the eleventh sacrifice layer with the second gate layer, comprises:
removing the ninth sacrifice layers through the gate line slit to form fifth gap layers;
forming the first source layer and the second source layer in two of the fifth gap layers respectively;
removing the sixth sacrifice layer, the seventh sacrifice layer, the eighth sacrifice layer, the tenth sacrifice layer and the eleventh sacrifice layer through the gate line slit to form a sixth gap layer, a seventh gap layer, an eighth gap layer, a ninth gap layer and a tenth gap layer; and
forming the first gate layer in both the sixth gap layer and the seventh gap layer, forming the intermediate layer in the eighth gap layer, and forming the second gate layer in both the ninth gap layer and the tenth gap layer.

19. The manufacturing method of semiconductor structure of claim 18, further comprises: before the forming the first source layer and the second source layer in two of the fifth gap layers respectively,
removing a portion of the channel structure through two of the fifth gap layers respectively, to form a redundant channel structure.

20. A memory system, comprising:
a semiconductor structure, comprising:
a first stack structure, comprising:
a plurality of channel structures, and
a first deck structure, a first intermediate structure and a second deck structure that are stacked, wherein the first intermediate structure is stacked between the first deck structure and the second deck structure, and the channel structures extend through the first deck structure, the first intermediate structure and the second deck structure along a stack direction, and
wherein the first intermediate structure comprises:
a first source layer;
a second source layer; and
an intermediate layer disposed between the first source layer and the second source layer, wherein the first source layer and the second source layer are connected with the channel structures respectively; and
a controller coupled to the semiconductor structure to control the semiconductor structure to store data.
